(19) United States
(12) Patent Application Publication
(10) Pub. No.: US 2026/0371588 A1
(43) Pub. Date: Nov. 19, 2026

(54) VERTICAL MEMORY DEVICES

(71) Applicant: Samsung Electronics Co., Ltd., Suwon-si (KR)

(72) Inventors: Kyungmoon Kim, Suwon-si (KR); Woo Young Choi, Seoul (KR); Junhyoung Kim, Suwon-si (KR); Sukkang Sung, Suwon-si (KR)

(73) Assignee: SEOUL NATIONAL UNIVERSITY R&DB FOUNDATION, Seoul (KR)

(21) Appl. No.: 19/678,499

(22) Filed: May 15, 2026

(30) Foreign Application Priority Data
May 16, 2025 (KR) 10-2025-0064198

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

A vertical memory device includes gate electrodes, a horizontal charge storage pattern and a memory channel structure. The gate electrodes are disposed on a substrate, and spaced apart from each other in a vertical direction perpendicular to an upper surface of the substrate. The horizontal charge storage pattern is disposed between the gate electrodes. The memory channel structure extends through the gate electrodes and the horizontal charge storage pattern in the vertical direction. The memory channel structure includes a channel and a vertical charge storage structure surrounding a sidewall of the channel. The horizontal charge storage pattern contacts a sidewall of the vertical charge storage structure. Each of the gate electrodes is spaced apart from the vertical charge storage structure in a horizontal direction parallel to the upper surface of the substrate.

### CROSS-REFERENCE TO RELATED APPLICATION(S)

This application claims priority under 35 U.S.C. § 119 to Korean Patent Application No. 10-2025-0064198, filed on May 16, 2025, the contents of which are herein incorporated by reference in their entirety.

### TECHNICAL FIELD

The present disclosure relates to a vertical memory device. More particularly, the present disclosure relates to a vertical NAND flash memory device.

### BACKGROUND

A vertical memory device includes gate electrodes disposed in a vertical direction, insulation layers between the gate electrodes, and memory channel structures extending in the vertical direction through the gate electrodes and the insulation layers. As the integration degree of the vertical memory device increases, the insulation layers have reduced thicknesses, and the interference may increase between memory cells vertically adjacent to each other.

### SUMMARY

The present application describes a semiconductor package that can reduce or prevent interfacial peeling and improve reliability.

According to one aspect of the subject matter described in this application, a vertical memory device includes gate electrodes, a horizontal charge storage pattern and a memory channel structure. The gate electrodes are disposed on a substrate, and are spaced apart from one another in a vertical direction perpendicular to an upper surface of the substrate. The horizontal charge storage pattern is disposed between the gate electrodes. The memory channel structure extends through the gate electrodes and the horizontal charge storage pattern in the vertical direction. The memory channel structure includes a channel and a vertical charge storage structure surrounding a sidewall of the channel. The horizontal charge storage pattern contacts a sidewall of the vertical charge storage structure. Each of the gate electrodes is spaced apart from the vertical charge storage structure in a horizontal direction parallel to the upper surface of the substrate.

According to another aspect, a vertical memory device may include gate electrodes, an insulation structure, a capping pattern, a memory channel structure, and a spacer. The gate electrodes are disposed on a substrate and spaced apart from one another in a vertical direction perpendicular to an upper surface of the substrate. The insulation structure is disposed between the gate electrodes and includes a first insulation pattern, a horizontal charge storage pattern, and a second insulation pattern that are stacked in the vertical direction. The capping pattern is disposed on a sidewall of the horizontal charge storage pattern. The memory channel structure extends through the gate electrodes and the insulation structure in the vertical direction. The memory channel structure includes a channel and a vertical charge storage structure disposed in a horizontal direction parallel to the upper surface of the substrate. The spacer is disposed on a lower surface and a sidewall of the first insulation pattern, an upper surface and a sidewall of the second insulation pattern, a sidewall of the capping pattern, and a sidewall of a portion of the vertical charge storage structure facing each of the gate electrodes in the horizontal direction.

According to another aspect, a vertical memory device includes gate electrodes, an insulation structure, a capping pattern, a memory channel structure and a spacer. The gate electrodes are disposed on a substrate and spaced apart from one another in a vertical direction perpendicular to an upper surface of the substrate. Each of the gate electrodes extends in a first direction parallel to an upper surface of the substrate. The insulation structure is disposed between the gate electrodes. The insulation structure includes a horizontal charge storage pattern extending in the first direction and insulation patterns on lower and upper surfaces, respectively, of the horizontal charge storage pattern. The capping pattern is disposed between the insulation patterns and disposed on a sidewall of the horizontal charge storage pattern in a second direction parallel to the upper surface of the substrate and crossing the first direction. The memory channel structure extends through the gate electrodes and the insulation structure in the vertical direction. The memory channel structure includes a filling pattern extending in the vertical direction, a channel surrounding the filling pattern, and a vertical charge storage structure surrounding the channel. The spacer is disposed on a lower surface, an upper surface and a portion of a sidewall of the insulation structure, a sidewall of the capping pattern, and a sidewall of a portion of the vertical charge storage structure facing each of the gate electrodes in the horizontal direction.

The vertical memory device may have enhanced efficiency of erase operation and improved data retention.

### BRIEF DESCRIPTION OF THE DRAWINGS

Example embodiments will be more clearly understood from the following detailed description taken in conjunction with the accompanying drawings.

FIGS. 1 to 6 are planar layout views and cross-sectional views illustrating an example of a vertical memory device.

FIG. 7 is a drawing for explaining an example of a role of the horizontal charge storage pattern in the vertical memory device.

FIG. 8 is a band diagram for explaining an example of energy bands distributed along line F-F′ passing through an end portion of the horizontal charge storage pattern during an erase operation of the vertical memory device.

FIG. 9 is a drawing explaining data retention characteristics according to a comparative example and an example embodiment of the present disclosure.

FIGS. 10 to 38 are plan views and cross-sectional views illustrating an example of a method of manufacturing a vertical memory device.

FIGS. 39 to 45 are cross-sectional views illustrating examples of vertical memory devices.

FIGS. 46 to 48 are cross-sectional views illustrating examples of vertical memory devices.

### DETAILED DESCRIPTION

The above and other aspects and features of a vertical memory device and a method of manufacturing the same in accordance with example embodiments will become readily understood from detail descriptions that follow, with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the teachings of disclosure.

When the terms “about” or “substantially” are used in relation to a numerical value, the value is considered to include manufacturing or operational tolerances (for example, ±10%) centered on the stated value. Additionally, when the terms “generally” or “substantially” are used in relation to a geometric shape, strict precision of the shape is not necessarily required, and a certain degree of flexibility in the shape is considered to fall within the scope of the present application.

Hereinafter, a vertical direction substantially perpendicular to an upper surface of a first substrate or a second substrate may be referred to as a first direction, and two directions among horizontal directions that are substantially parallel to the upper surface of the first substrate or the second substrate, which may be substantially perpendicular to each other, may be referred to as second and third directions D2 and D3, respectively. In example embodiments, the second and third directions D2 and D3 may be substantially perpendicular to each other.

Each of the first to third directions D1, D2 and D3 may include not only a direction indicated by an arrow in the drawings but also a direction opposite thereto.

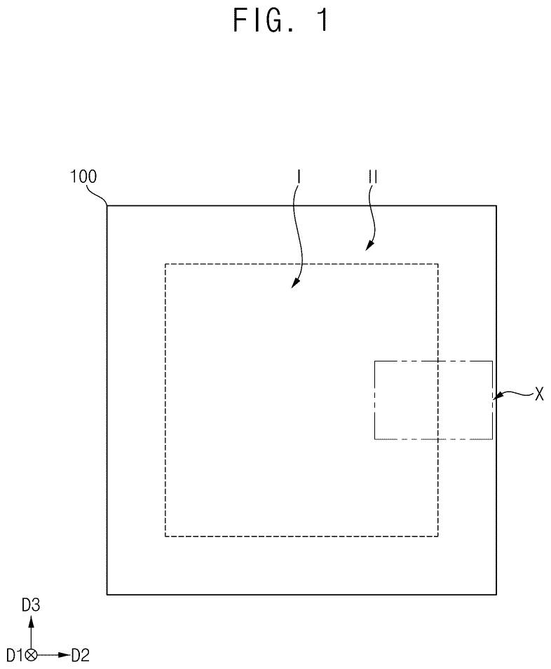

FIGS. 1 to 6 are planar layout views and cross-sectional views illustrating a vertical memory device in accordance with example embodiments.

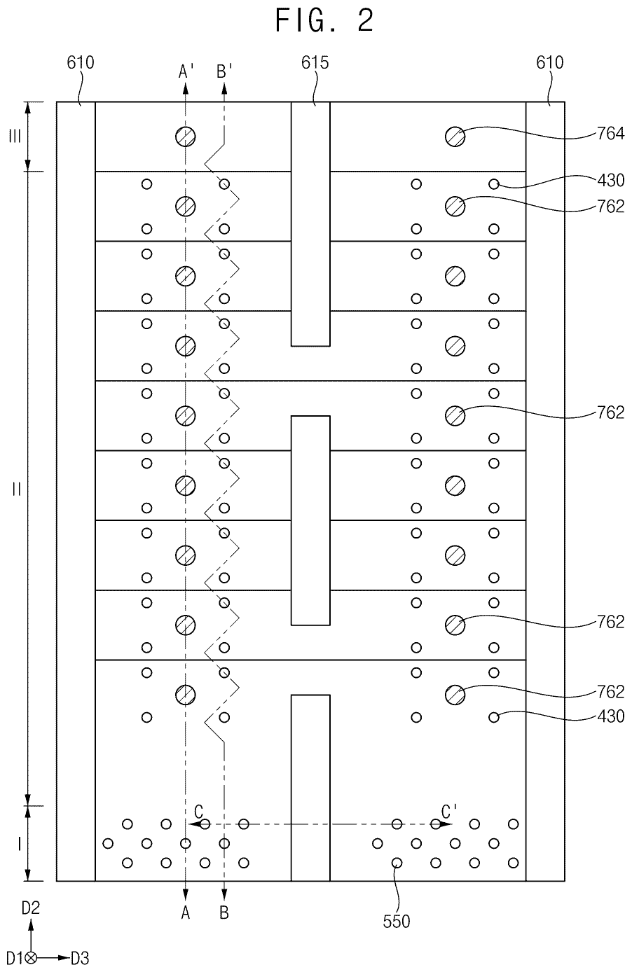

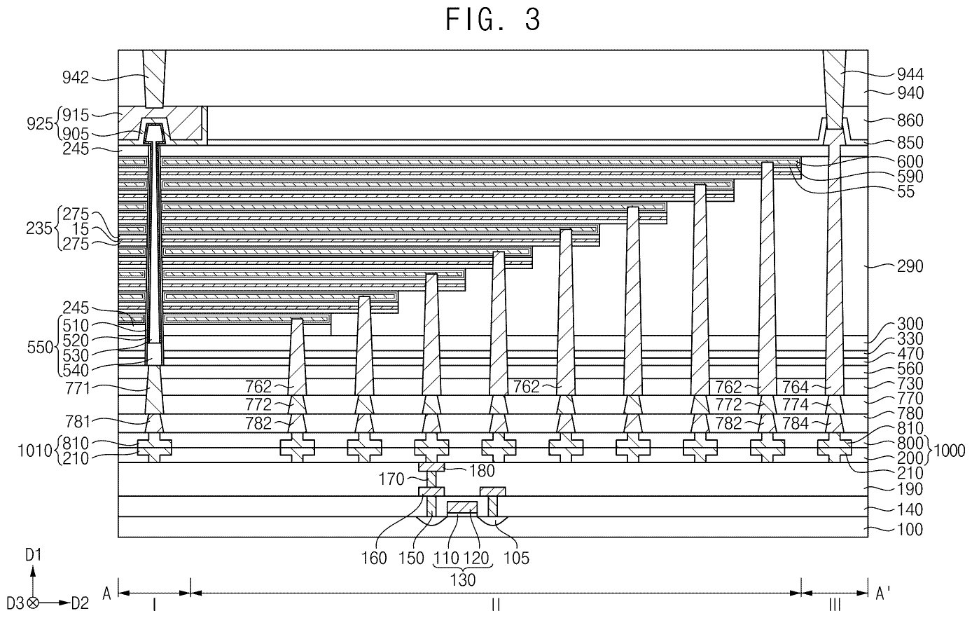

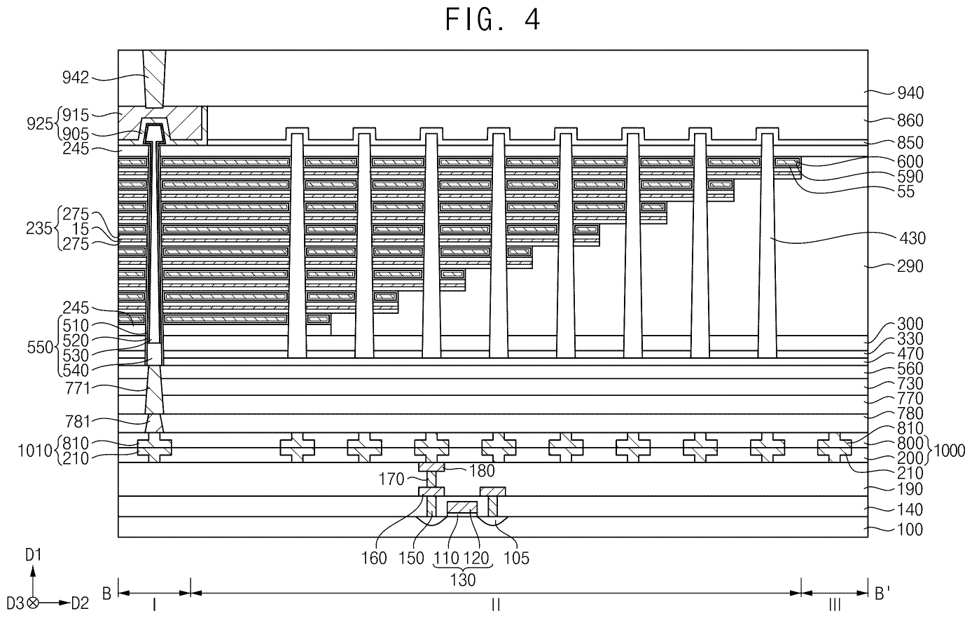

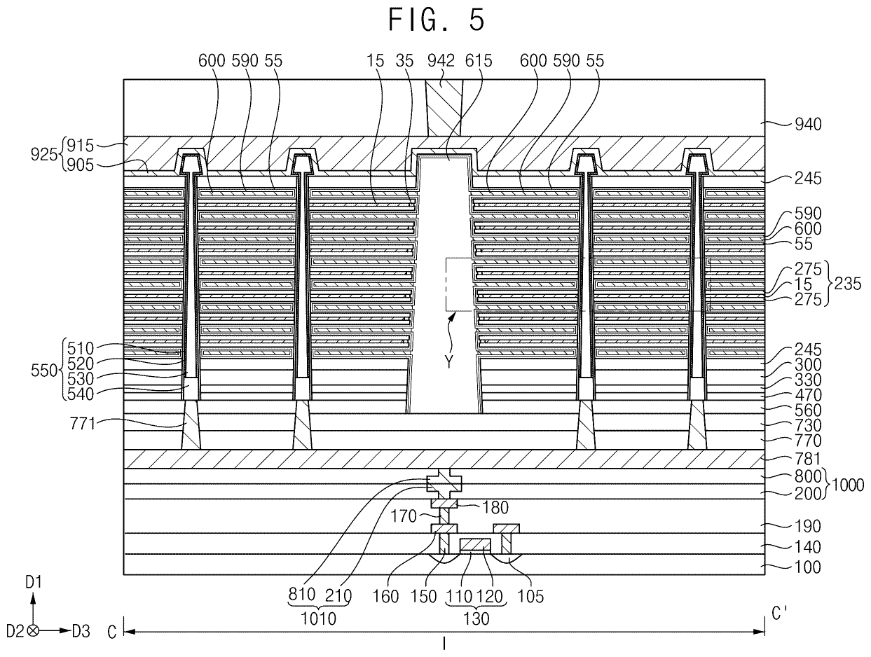

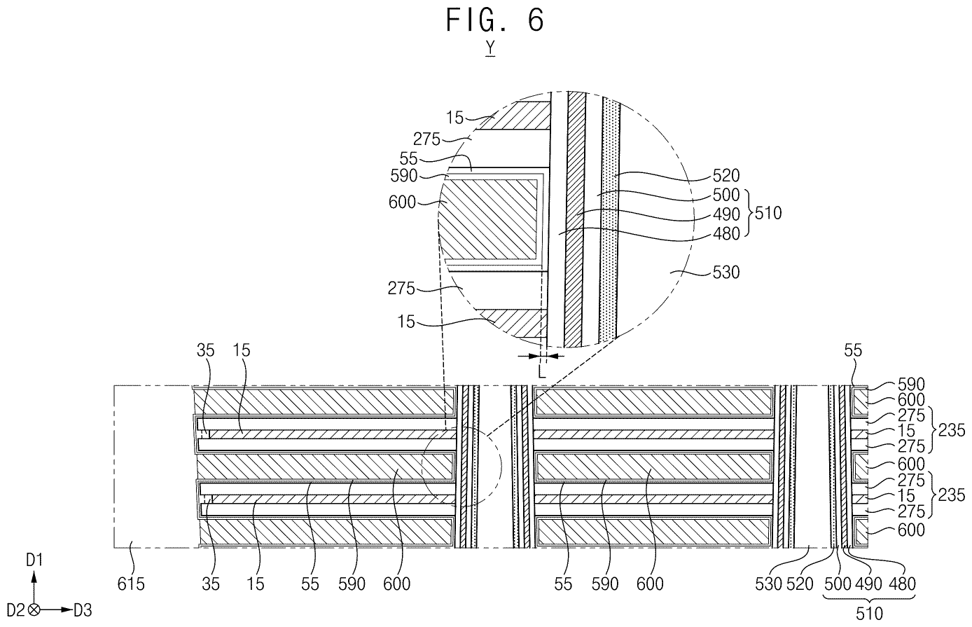

Particularly, FIG. 1 is a planar layout view illustrating regions of the vertical memory device, FIG. 2 is a planar layout view illustrating some elements of the vertical memory device, FIG. 3 is a cross-sectional view taken along line A-A′ of FIG. 2, FIG. 4 is a cross-sectional view taken along line B-B′ of FIG. 2, FIG. 5 is a cross-sectional view taken along line C-C′ of FIG. 2, and FIG. 6 is an enlarged cross-sectional view of region Y of FIG. 5. FIGS. 2 to 6 are drawing of region X of FIG. 1.

Referring to FIGS. 1 to 6, the vertical memory device may include a lower circuit pattern, a bonding layer structure 1000, a second gate electrode structure, a memory channel structure 550, a support structure 430, a second insulation structure 235, a second capping pattern 35, a spacer 55, a second blocking pattern 590 and a common source plate (CSP) structure 925 on a first substrate 100.

The vertical memory device may further include second to fourth contact plugs 762, 942 and 944, a through via 764, second to fourth vias 771, 772 and 774, third to fifth wirings 781, 782 and 784, first and second division patterns 610 and 615, a third division pattern, a first insulation pattern 245, first to twelfth insulating interlayers 140, 190, 940, 860, 780, 770, 730, 560, 470, 330, 300, 290, and an etch stop layer 850.

The vertical memory device may include first, second and third regions I, II and III. In example embodiments, the first region I of the vertical memory device may be a cell array region in which memory cells are disposed, the second region II of the vertical memory device may be a pad region or an extension region in which the second contact plugs 762 for transmitting electrical signals to the memory cells are disposed, and the first and second regions I and II may collectively form a cell region. The third region III of the vertical memory device may be a peripheral circuit region in which a peripheral circuit pattern is disposed. In example embodiments, the second region II may surround the first region I or may be disposed at each of opposite sides in the second direction D2, and the third region III may surround the first and second regions I and II.

In some embodiments, the vertical memory device may have a cell over periphery (COP) structure. That is, the memory cells may be disposed over the periphery circuit pattern, and thus the periphery circuit pattern may be disposed not only in the third region III but also under the first and second regions I and II, which may form the lower circuit pattern.

However, the present disclosure is not limited thereto, and for example, the vertical memory device may also have a periphery over cell (POC) structure. In this case, the memory cells may be disposed under the periphery circuit pattern, and the periphery circuit pattern may be disposed not only in the third region III but also over the first and second regions I and II, which may form an upper circuit pattern.

The first substrate 100 may include a semiconductor material, e.g., silicon, germanium, silicon-germanium, etc., or a III-V group compound semiconductor, e.g., GaP, GaAs, GaSb, etc. In example embodiments, the first substrate 100 may be a silicon-on-insulator (SOI) substrate or a germanium-on-insulator (GOI) substrate.

The lower circuit pattern may include, e.g., a transistor, a first contact plug 150, first and second wirings 160 and 180, and a first via 170.

The transistor may include a gate structure 130 on the first substrate 100, and first impurity regions 105 at an upper portion of the first substrate 100 adjacent to the gate structure 130, which may serve as source/drains, respectively. The gate structure 130 may include a gate insulation pattern 110 and a first gate electrode 120 stacked on the first substrate 100.

The gate insulation pattern 110 may include an oxide, e.g., silicon oxide, and the first gate electrode 120 may include a conductive material, e.g., a metal, a metal nitride, a metal silicide, doped polysilicon, etc.

The first insulating interlayer 140 may be disposed on the first substrate 100 and may cover the transistor, and the first contact plug 150 may extend through the first insulating interlayer 140 and contact each of the first impurity regions 105.

The first wiring 160 may be disposed on the first insulating interlayer 140 and may contact an upper surface of the first contact plug 150. The first via 170 and the second wiring 180 may be sequentially stacked on the first wiring 160 in the first direction D1.

The second insulating interlayer 190 may be disposed on the first insulating interlayer 140 and may cover the first and second wirings 160 and 180 and the first via 170.

Each of the first and second insulating interlayers 140 and 190 may include an oxide, e.g., silicon oxide, and in some cases, may be merged with each other.

The bonding layer structure 1000 may include first and second bonding layers 200 and 800 sequentially stacked in the first direction D1. First and second bonding pads 210 and 810 may be disposed in the first and second bonding layers 200 and 800, respectively, and may contact each other to form a bonding pad structure 1010. The first bonding pad 210 may contact a portion of the lower circuit pattern, e.g., the second wiring 180 and may be electrically connected thereto.

In some embodiments, the first bonding pad 210 may include a lower portion having a relatively small width and an upper portion having a relatively large width, and the second bonding pad 810 may include a lower portion having a relatively large width and an upper portion having a relatively small width.

Each of the first and second bonding layers 200 and 800 may include, e.g., silicon carbonitride or silicon oxide, and each of the first and second bonding pads 210 and 810 may include a metal, e.g., copper.

The fifth to twelfth insulating interlayers 780, 770, 730, 560, 470, 330, 300 and 290 may be sequentially stacked in the first direction D1 on the bonding layer structure 1000. Each of the fifth to twelfth insulating interlayers 780, 770, 730, 560, 470, 330, 300 and 290 may include an oxide, e.g., silicon oxide, and some of the fifth to twelfth insulating interlayers 780, 770, 730, 560, 470, 330, 300 and 290 may be merged with each other.

Each of the third to fifth wirings 781, 782 and 784 may extend through the fifth insulating interlayer 780 and may contact an upper surface of the second bonding pad 810, the second via 771 may extend through the sixth to eighth insulating interlayers 770, 730 and 560 and contact an upper surface of the third wiring 781, and the third and fourth vias 772 and 774 may extend through the sixth insulating interlayer 770 and contact upper surfaces of the fourth and fifth wirings 782 and 784, respectively. The third wiring 781 and the second via 771 may be disposed in the first region I, the fourth wiring 782 and the third via 772 may be disposed in the second region II, and the fifth wiring 784 and the fourth via 774 may be disposed in the third region III.

In example embodiments, the third wiring 781 may extend in the third direction D3 and a plurality of third wirings 781 may be spaced apart from each other in the second direction D2 in the first region I. The third wiring 781 may serve as a bit line of the vertical memory device, and may be electrically connected to the memory channel structure 550 through the second via 771.

The second gate electrode structure may include second gate electrodes 600, each of which may extend in the second direction D2, disposed at a plurality of levels, respectively, that are spaced apart from each other in the first direction D1. In example embodiments, a plurality of second gate electrode structures may be spaced apart from each other in the third direction D3, and the first division pattern 610 may be interposed between ones of the second gate electrode structures neighboring in the third direction D3.

In example embodiments, the first division pattern 610 may extend in the second direction D2, and a plurality of first division patterns 610 may be spaced apart from each other in the third direction D3 in the first and second regions I and II. The second division pattern 615 may be disposed between ones of the first division patterns 610 neighboring in the third direction D3, and may extend through the second gate electrode structure.

The second division pattern 615 may not continuously extend in the second direction D2 in the first and second regions I and II, but a plurality of second division patterns 615 may be spaced apart from each other in the second direction D2 in the first and second regions I and II. Thus, the second gate electrode structure may not be entirely separated in the third direction D3 by the second division pattern 615.

Each of the first and second division patterns 610 and 615 may extend through the eighth to eleventh insulating interlayers 560, 470, 330 and 300, the second gate electrode structure and the first insulation patterns 245. Each of the first and second division patterns 610 and 615 may have a width gradually decreasing from a top toward a bottom thereof in the first direction D1, and thus each of opposite sidewalls in the third direction D3 of each of the first and second division patterns 610 and 615 may be slanted with respect to the upper surface of the first substrate 100. Each of the first and second division patterns 610 and 615 may include an oxide, e.g., silicon oxide.

In example embodiments, some of the second gate electrodes 600, e.g., an uppermost one of the second gate electrodes 600 may serve as a ground select line (GSL), some of the second gate electrodes 600, e.g., a lowermost one and a second one from below of the second gate electrodes 600 may serve as a string select line (SSL), and other ones of the second gate electrodes 600 between the GSL and the SSL may serve as word lines, respectively.

In some embodiments, some of the second gate electrodes 600, e.g., the uppermost one and other ones adjacent thereto in the first direction D1 of the second gate electrodes 600 or the lowermost one and other ones adjacent thereto in the first direction D1 of the second gate electrodes 600 may serve as a gate induced drain leakage (GIDL) gate electrode, which may be used in an erase operation for erasing data stored in the memory channel structure 550 by a GIDL phenomenon.

In example embodiments, each of the second gate electrodes 600 may have a plane shape extending in the second direction D2 in the first and second regions I and II, and extension lengths in the second direction D2 of the second gate electrodes 600 disposed in the first direction D1 may increase in a stepwise manner from the lowermost one to the uppermost one of the second gate electrodes 600. Thus, the second gate electrode structure may have an inverted staircase shape. In some embodiments, a thickness in the first direction D1 of the second gate electrode 600 may be in a range of about 15 nm to about 33 nm.

The second gate electrode 600 may include a gate conductive pattern and a gate barrier pattern covering a surface of the gate conductive pattern. The gate conductive pattern may include a low resistance metal, e.g., tungsten, titanium, tantalum, platinum, etc., and the gate barrier pattern may include a metal nitride, e.g., titanium nitride, tantalum nitride, etc.

In example embodiments, upper and lower surfaces and opposite sidewalls in the second direction D2 of the second gate electrode 600 and sidewalls facing the memory channel structure 550 may be covered by a second blocking pattern 590, and a surface of the second blocking pattern 590 may be covered by the spacer 55. In some embodiments, the spacer 55 may have a thickness of about 1.5 nm to about 2.5 nm.

The second blocking pattern 590 may include a metal oxide, e.g., aluminum oxide, and the spacer 55 may include, e.g., silicon oxide or a low-k dielectric material.

The first insulation pattern 245 may extend in the second direction D2 on the uppermost one of the second gate electrodes 600 and beneath the lowermost one of the second gate electrodes 600, and may contact a surface of the spacer 55. The first insulation pattern 245 beneath the lowermost one of the second gate electrodes 600 may contact an upper surface of the eleventh insulating interlayer 300, and in some cases, may be merged thereto. The first insulation pattern 245 may include, e.g., silicon oxide.

In example embodiments, the second insulation structure 235 may extend between ones of the second gate electrodes 600 neighboring in the first direction D1, and a plurality of second insulation structures 235 may be spaced apart from each other in the first direction D1. Each of the second insulation structure 235 may contact the surface of the spacer 55.

In example embodiments, the second insulation structure 235 may include second insulation patterns 275 spaced apart from each other in the first direction D1 and a horizontal charge storage pattern 15 between the second insulation patterns 275. In example embodiments, the horizontal charge storage pattern 15 may have a plane shape extending in the second direction D2. A width in the third direction D3 of the horizontal charge storage pattern 15 in the second insulation structure 235 may be smaller than a width in the third direction D3 of each of the second insulation patterns 275 included in the same second insulation structure 235 and may be smaller than a width in the third direction D3 of each of the second gate electrodes 600 disposed on and beneath the second insulation structure 235.

The second insulation pattern 275 may include an oxide, e.g., silicon oxide, and the horizontal charge storage pattern 15 may include an insulating nitride, e.g., silicon nitride or a metal oxide, e.g., hafnium oxide, hafnium zinc oxide, etc.

In example embodiments, the second capping pattern 35 may be disposed at and contact an end portion in the third direction D3 of the horizontal charge storage pattern 15, and may contact a lower surface of the second insulation pattern 275 on the horizontal charge storage pattern 15 and an upper surface of the second insulation pattern 275 beneath the horizontal charge storage pattern 15. In some embodiments, a sidewall in the third direction D3 of the second capping pattern 35 may not be aligned with the sidewalls in the third direction D3 of the second insulation patterns 275 on and beneath the horizontal charge storage pattern 15, but may be offset thereto in the third direction D3.

The spacer 55 may cover an upper surface and a sidewall in the third direction D3 of an upper one of the second insulation patterns 275 included in each of the second insulation structure 235, a lower surface and a sidewall in the third direction D3 of a lower one of the second insulation patterns 275 included in each of the second insulation structure 235, and a sidewall in the third direction D3 of the second capping pattern 35 between the lower one and the upper one of the second insulation patterns 275 included in each of the second insulation structure 235.

The second capping pattern 35 may include an oxide, e.g., silicon oxide or a low-k dielectric material, and in some cases, may be merged to the spacer 55.

The memory channel structure 550 may extend through the second gate electrode structure, the second insulation structure 235, the first insulation patterns 245, and the ninth to eleventh insulating interlayers 470, 330 and 300 in the first direction D1 in the first region I, and may contact an upper surface of the second via 771.

In example embodiments, a plurality of memory channel structures 550 may be disposed in each of the second and third direction D2 and D3 through each of the second gate electrode structures that are separated by ones of the first division patterns 610 neighboring in the third direction D3, and each of the second gate electrode structures and the plurality of memory channel structures 550 may form a memory block. In example embodiments, a plurality of memory blocks may be disposed in the third direction D3. In some embodiments, the memory channel structure 550 may have a width gradually decreasing from a bottom toward a top thereof in the first direction D1, and thus a sidewall of the memory channel structure 550 may be slanted with respect to the upper surface of the first substrate 100.

The memory channel structure 550 may include a first capping pattern 540, a filling pattern 530, a channel 520 and a vertical charge storage structure 510.

The first capping pattern 540 may extend through the ninth and tenth insulating interlayers 470 and 330 and a lower portion of the eleventh insulating interlayer 300, and may contact the upper surface of the second via 771. The first capping pattern 540 may include, e.g., undoped polysilicon or polysilicon doped with n-type or p-type impurities.

The filling pattern 530 may include a lower portion and an upper portion. The lower portion of the filling pattern 530 may contact an upper surface of a central portion of the first capping pattern 540, and may extend through an upper portion of the eleventh insulating interlayer 300, lower and upper ones of the first insulation patterns 245, the second gate electrode structure and the second insulation structure 235 in the first direction D1. The upper portion of the filling pattern 530 may be disposed on and contact the lower portion of the filling pattern 530, and may protrude from the upper one of the first insulation patterns 245 upwardly. In some embodiments, a width of the upper portion of the filling pattern 530 may be greater than a width of the lower portion of the filling pattern 530. The filling pattern 530 may include an oxide, e.g., silicon oxide.

The channel 520 may cover a sidewall and an upper surface of the filling pattern 530, and may contact an upper surface of an edge of the first capping pattern 540. The channel 520 may include a lower portion and an upper portion corresponding to the lower portion and the upper portion of the filling pattern 530. The upper portion of the channel 520 may extend through the upper portion of the eleventh insulating interlayer 300, the lower and upper ones of the first insulation patterns 245, the second gate electrode structure and the second insulation structure 235 in the first direction D1. The upper portion of the channel 520 may be disposed on and contact the lower portion of the channel 520, and may protrude from the upper one of the first insulation patterns 245 upwardly. The channel 520 may include, e.g., undoped polysilicon.

The vertical charge storage structure 510 may cover a sidewall of the first capping pattern 540 and an outer sidewall of the lower portion of the channel 520, and may extend through the ninth to eleventh insulating interlayers 470, 330 and 300, the lower and upper ones of the first insulation patterns 245, the second gate electrode structure and the second insulation structure 235 in the first direction D1. The vertical charge storage structure 510 may contact sidewalls of the ninth to eleventh insulating interlayers 470, 330 and 300, the lower and upper ones of the first insulation patterns 245, a sidewall of the spacer 55 and a sidewall of the second insulation structure 235.

The vertical charge storage structure 510 may include a tunnel insulation pattern 500, a vertical charge storage pattern 490 and a first blocking pattern 480 sequentially stacked in the horizontal direction from the outer sidewall of the lower portion of the channel 520. The tunnel insulation pattern 500 may include an oxide, e.g., silicon oxide, the vertical charge storage pattern 490 may include an insulating nitride, e.g., silicon nitride, and the first blocking pattern 480 may include an oxide, e.g., silicon oxide.

The horizontal charge storage pattern 15 may contact a sidewall of the first blocking pattern 480, and in some cases, the horizontal charge storage pattern 15 and the first blocking pattern 480 may be merged with each other.

In example embodiments, the horizontal charge storage pattern 15 may contact a sidewall of the memory channel structure 550, that is, an outer sidewall of the first blocking pattern 480 of the vertical charge storage structure 510, and the second gate electrode 600 may be spaced apart from the sidewall of the memory channel structure 550, that is, the outer sidewall of the first blocking pattern 480 by the second blocking pattern 590 and the spacer 55. Accordingly, a distance from the memory channel structure 550 to the second gate electrode 600 may be greater than a distance from the horizontal charge storage pattern 15 to the memory channel structure 550.

The horizontal charge storage pattern 15 may protrude toward the memory channel structure 550 by a length L in the horizontal direction when compared to a portion of the second blocking pattern 590 on a sidewall of the second gate electrode 600 facing the memory channel structure 550, and the length L may be substantially the same as a thickness of the spacer 55. As the thickness of the spacer 55 increases, the length L may increase.

The support structure 430 may extend through the tenth to twelfth insulating interlayers 330, 300 and 290, the first insulation patterns 245, a portion of the second gate electrode structure and the second insulation structure 235 in the first direction D1 in the second region II, and may protrude from the upper one of the first insulation patterns 245 upwardly. The support structure 430 may contact sidewalls of the tenth to twelfth insulating interlayers 330, 300 and 290, the sidewalls of the first insulation patterns 245, the sidewall of the spacer 55 and the sidewall of the second insulation structure 235. In some embodiments, the support structure 430 may have a width gradually decreasing from a bottom toward a top thereof in the first direction D1, and a sidewall of the support structure 430 may be slanted with respect to the upper surface of the first substrate 100.

In example embodiments, a plurality of support structures 430 may be spaced apart from each other in each of the second and third directions D2 and D3 in the second region II. In some embodiments, the support structures 430 may be disposed at vertices of a rectangle in a plan view. The support structure 430 may include an oxide, e.g., silicon oxide.

In example embodiments, a plurality of second contact plugs 762 may be spaced apart from each other in each of the second and third directions D2 and D3 in the second region II. Each of the second contact plugs 762 may contact an upper surface of the third via 772, and may extend through the seventh to twelfth insulating interlayers 730, 560, 470, 330, 300 and 290, the second insulation structure 235, the spacer 55 and the second blocking pattern 590 to contact a lower surface of the second gate electrode 600.

In some embodiments, the second contact plug 762 may be disposed in an inside of the rectangle in a plan view. In some embodiments, the second contact plug 762 may have a width gradually decreasing from a bottom toward a top thereof in the first direction D1, and a sidewall of the second contact plug 762 may be slanted with respect to the upper surface of the first substrate 100.

In example embodiments, a plurality of through vias 764 may be spaced apart from each other in each of the second and third directions D2 and D3 in the third region III. The through via 764 may contact an upper surface of the fourth via 774, and may extend through the seventh to twelfth insulating interlayers 730, 560, 470, 330, 300 and 290 and the upper one of the first insulation patterns 245 to protrude from the upper one of the first insulation pattern 245 upwardly. In example embodiments, the through via 764 may have a width gradually decreasing from a bottom toward a top thereof in the first direction D1, and a sidewall of the through via 764 may be slanted with respect to the upper surface of the first substrate 100.

The etch stop layer 850 may be disposed on upper surfaces of the upper one of the first insulation patterns 245 and the through via 764, and the fourth insulating interlayer 860 may be disposed on the etch stop layer 850. The etch stop layer 850 may include an insulating interlayer nitride, e.g., silicon nitride, and the fourth insulating interlayer 860 may include an oxide, e.g., silicon oxide.

The CSP structure 925 may be disposed on the upper one of the first insulation patterns 245, the memory channel structure 550 and the spacer 55 in the first region I. The CSP structure 925 may contact a surface of the upper portion of the channel 520 included in the memory channel structure 550, and may be electrically connected thereto.

In example embodiments, the CSP structure 925 may include a conductive pattern 915 and a barrier pattern 905 covering a lower surface and a sidewall of the conductive pattern. The barrier pattern 905 may include a metal nitride, e.g., titanium nitride, tungsten nitride, molybdenum nitride, tantalum nitride, etc., and the conductive pattern 915 may include a metal, e.g., tungsten, molybdenum, tantalum, ruthenium, niobium, osmium, zirconium, iridium, rhenium, titanium, etc.

Alternatively, the CSP structure 925 may include the conductive pattern 915, the barrier pattern 905, and a polysilicon pattern covering a lower surface and a sidewall of the barrier pattern 905. The polysilicon pattern may include n-type or p-type impurities.

In example embodiments, a plurality of memory channel structures 550 may be spaced apart from each other in each of the second and third directions D2 and D3 in each of the memory blocks to form a memory channel array, and a plurality of channels 520 included in the memory channel array may be electrically connected to each other by the CSP structure 925.

The third division pattern may extend through the CSP structure 925, the spacer 55 and the second blocking pattern 590 to contact an upper surface of the first division pattern 610, and may divide the CSP structure 925 into a plurality of parts in the third direction D3. Thus, the plurality of channels 520 included in each of the memory blocks may be electrically connected to a single CSP structure 925.

Each of the first to fourth contact plugs 150, 762, 942 and 944, the through via 764, the first to fourth vias 170, 771, 772 and 774, and the first to fifth wirings 160, 180, 781, 782 and 784 may include a conductive material, e.g., a metal, a metal nitride, a metal silicide, etc.

The vertical memory device may include the second insulation structure 235 between the second gate electrodes 600 disposed in the first direction D1, and the second insulation structure 235 may include the second insulation patterns 275 disposed in the first direction D1 and the horizontal charge storage pattern 15 interposed therebetween. As the vertical memory device further includes the horizontal charge storage pattern 15 in addition to the vertical charge storage pattern 490, as described below, lateral migration in the vertical charge storage pattern 490 may be reduced, and thus the vertical memory device may have enhanced electrical characteristics.

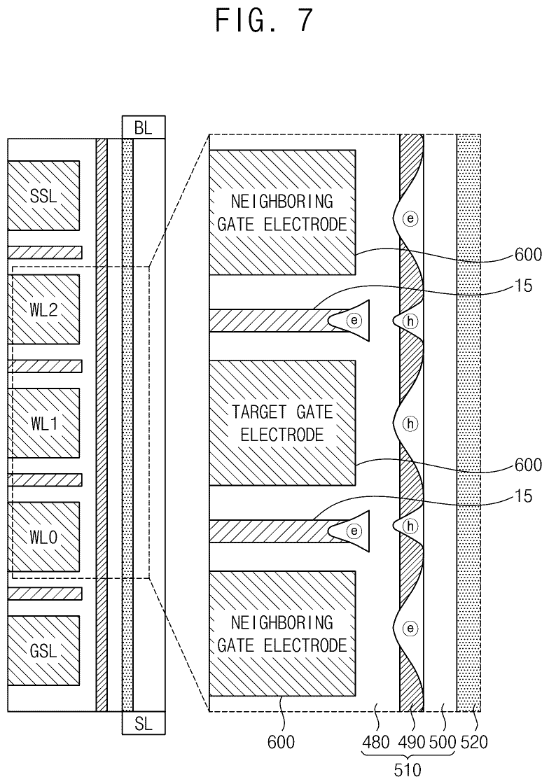

FIG. 7 is a drawing for explaining a role of the horizontal charge storage pattern in the vertical memory device.

Referring to FIG. 7, when a program voltage is applied to each of the second gate electrodes 600, electrons present in the channel 520 included in the memory channel structure 550 may pass through the tunnel insulation pattern 500 and be trapped in the vertical charge storage pattern 490, thereby performing a program operation. Due to a fringing effect of an electric field generated by the program voltage, some electrons may also be trapped to an inside of the horizontal charge storage pattern 15 disposed between the second gate electrodes 600, particularly, in a portion of the horizontal charge storage pattern 15 adjacent to the memory channel structure 550.

When an erase voltage is applied to a target gate electrode among the second gate electrodes 600, holes present in the channel 520 may pass through the tunnel insulation pattern 500 and be trapped in the vertical charge storage pattern 490, thereby recombining electrons and being annihilated, so that an erase operation may be performed. A so-called back tunneling phenomenon may occur in which some electrons included in the target gate electrode pass through the first blocking pattern 480 and move into the vertical charge storage pattern 490. Due to the back tunneling phenomenon, some of the electrons may remain in the vertical charge storage pattern 490, thereby degrading the efficiency of the erase operation of the vertical memory device.

However, in example embodiments, the horizontal charge storage pattern 15 may be disposed between the target gate electrode and the adjacent gate electrode, that is, disposed adjacent to the target gate electrode. Due to an electric field formed by electrons trapped in the horizontal charge storage pattern 15, the back tunneling phenomenon may be reduced, thereby increasing the efficiency of the erase operation of the vertical memory device.

Particularly, the horizontal charge storage pattern 15 may protrude toward the memory channel structure 550 by the length L in the horizontal direction when compared to the portion of the second blocking pattern 590 on the sidewall of the second gate electrode 600 facing the memory channel structure 550, and the fringing effect may be concentrated on the protruding portion of the horizontal charge storage pattern 15, the back tunneling phenomenon may be further reduced and the efficiency of the erase operation of the vertical memory device may be further increased.

Even during a period in which the program operation and/or the erase operation is not performed, a so-called lateral migration phenomenon may occur in which changes move in the vertical direction within the vertical charge storage pattern 490 due to an electric field formed by interactions between electrons and holes present in the vertical charge storage pattern 490. As a result, a threshold voltage may vary, thereby degrading data retention characteristics of the vertical memory device.

However, in example embodiments, electrons trapped in the horizontal charge storage pattern 15 disposed between the second gate electrodes 600 may exert an attractive force on holes present in a portion of the vertical charge storage pattern 490 adjacent thereto, while exerting a repulsive force on electrons present in portions of the vertical charge storage pattern 490 adjacent to each of the second gate electrodes 600. Accordingly, a lateral migration phenomenon in which charges present in the vertical charge storage pattern 490 move in the vertical direction may be suppressed, and thus data retention characteristics of the vertical memory device may be improved.

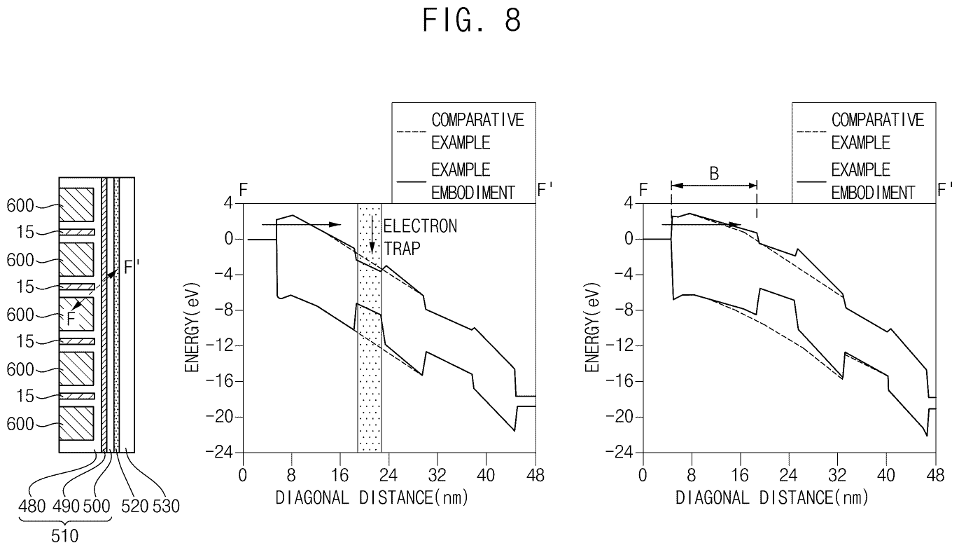

FIG. 8 is a band diagram for explaining energy bands distributed along line F-F′ passing through an end portion of the horizontal charge storage pattern during an erase operation of the vertical memory device. In FIG. 8, a dotted line represents energy bands according to a comparative example that does not include the horizontal charge storage pattern, and a solid line represents energy bands according to an example embodiment that includes the horizontal charge storage pattern.

Referring to FIG. 8, in the energy band according to the example embodiment, (a) when an erase voltage is applied to the second gate electrodes 600, electrons may be trapped in the horizontal charge storage pattern 15 adjacent to each of the second gate electrodes 600 due to a fringing effect of an electric field generated by the erase voltage, and thus a difference between an energy level of a conduction band and an energy level of a valence band may be reduced.

Thereafter, (b) when sufficient electrons are trapped in the horizontal charge storage pattern 15, the energy level of the conduction band may increase due to the trapped electrons. Accordingly, a barrier B may increase, thereby reducing a back tunneling phenomenon from each of the second gate electrodes 600 to the vertical charge storage pattern 490. In some examples, the sufficient electrons may be predetermined.

Instead of applying the erase voltage to each of the second gate electrodes 600, a program voltage may be applied to each of the gate electrodes 600, so that electrons may be trapped in the horizontal charge storage pattern 15.

That is, among the second gate electrodes 600 included in a string and disposed in the first direction D1, for example, a program voltage having a positive value may be applied to first ones of the second gate electrodes 600 disposed at odd-numbered levels and a program voltage having a value of 0V may be applied to second ones of the second gate electrodes 600 disposed at even-numbered levels, electrons may move from the second ones of the second gate electrodes 600 toward the first ones of the second gate electrodes 600 adjacent thereto, and may be trapped in the horizontal charge storage pattern 15 disposed therebetween.

Self-boosting may be implemented by applying the same voltage to a string select line SSL and a ground select line GSL respectively disposed at both ends of the string, and to a bit line BL and a source line SL electrically connected to the string, thereby placing the string in a program inhibit state. Accordingly, the electrons may be prevented from moving into the vertical charge storage pattern 490.

As described above, when sufficient electrons are trapped in the horizontal charge storage pattern 15, as shown in (b) of FIG. 8, a barrier B may increase, thereby reducing a back tunneling phenomenon from each of the second gate electrodes 600 to the vertical charge storage pattern 490.

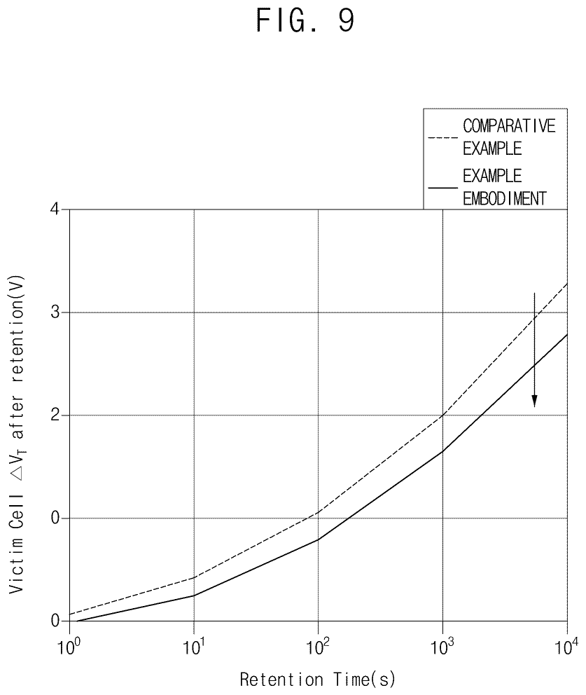

FIG. 9 is a drawing explaining data retention characteristics according to a comparative example and an example embodiment of the present disclosure.

In FIG. 9, a dotted line represents data retention characteristics according to the comparative example that does not include the horizontal charge storage pattern, and a solid line represents data retention characteristics according to the example embodiment that includes the horizontal charge storage pattern.

Referring to FIG. 9, a difference in threshold voltage over time in the vertical memory device according to the example embodiment is smaller than a difference in threshold voltage over time in the vertical memory device according to the comparative example.

Accordingly, in the vertical memory device in some embodiments, a variation in threshold voltage over time may be reduced, thereby securing improved data retention characteristics.

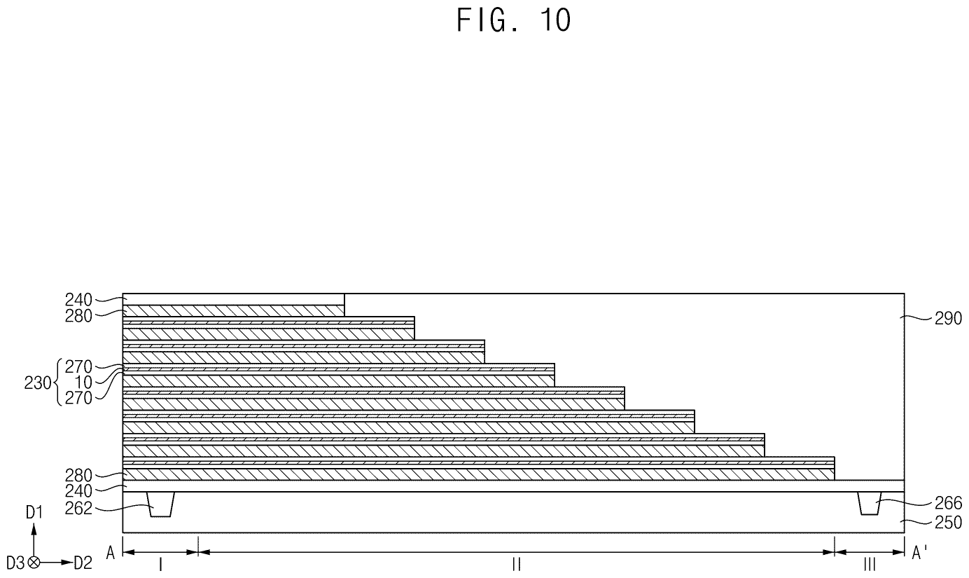

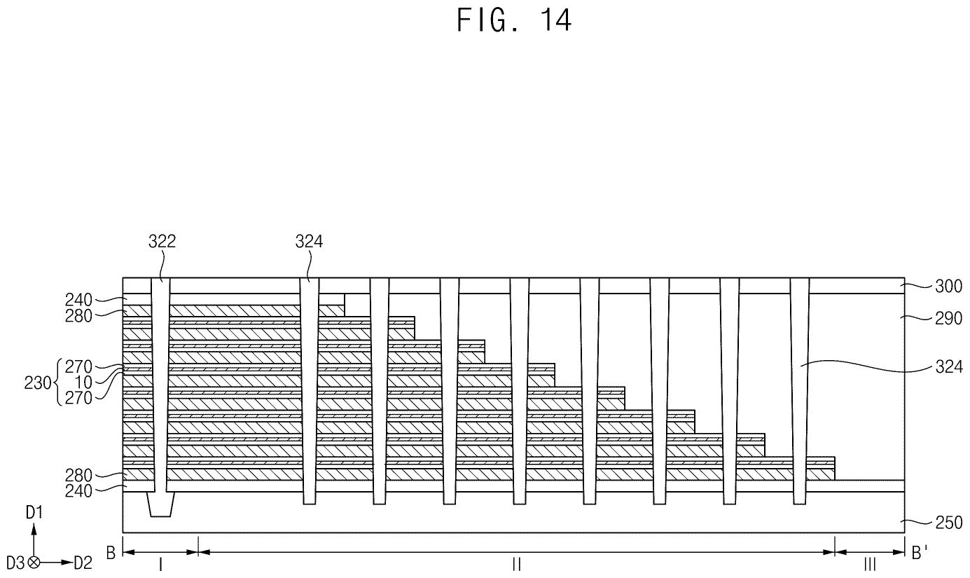

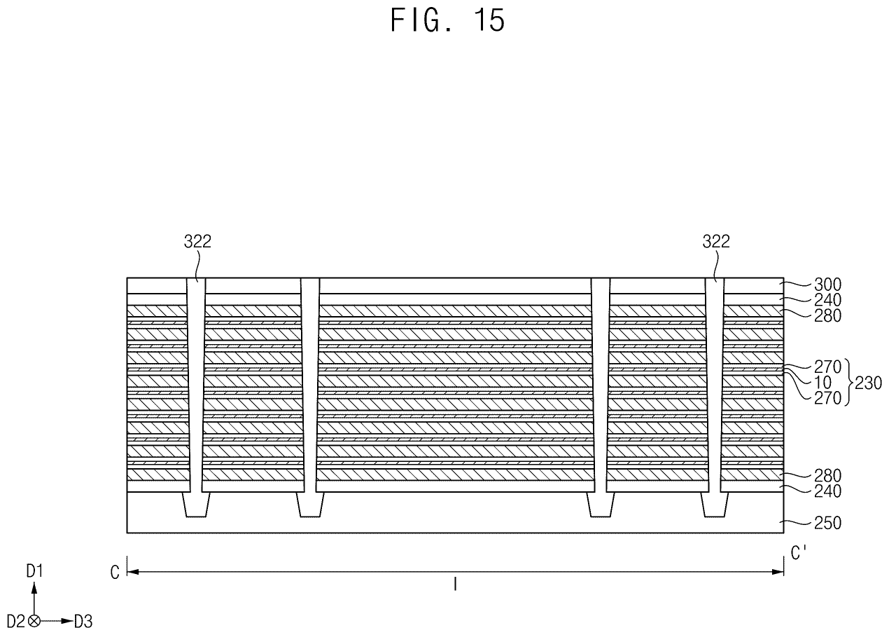

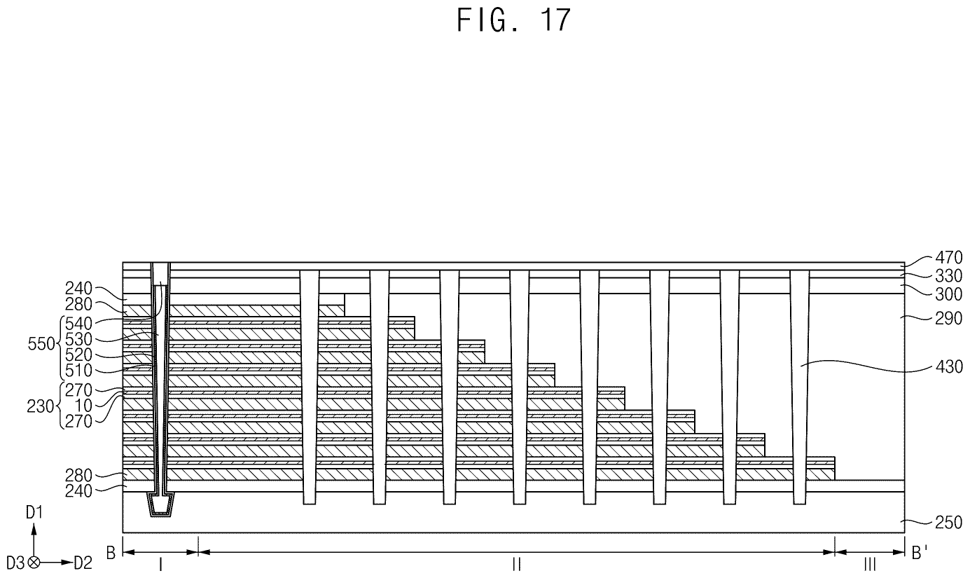

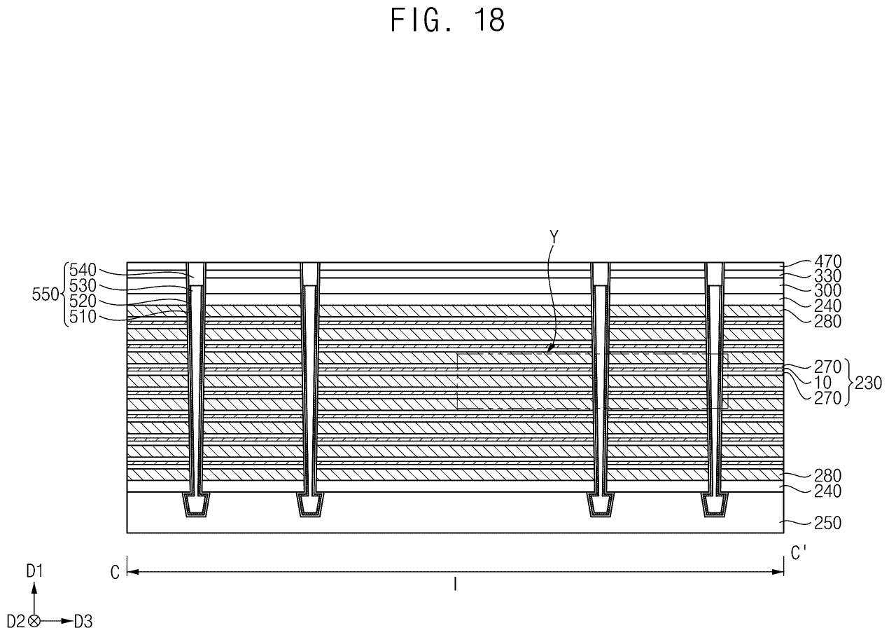

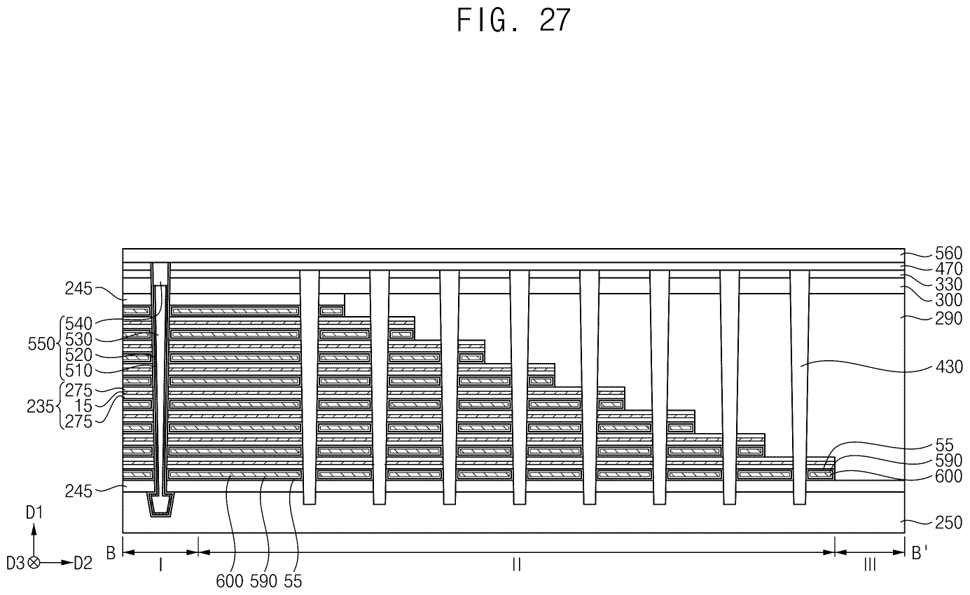

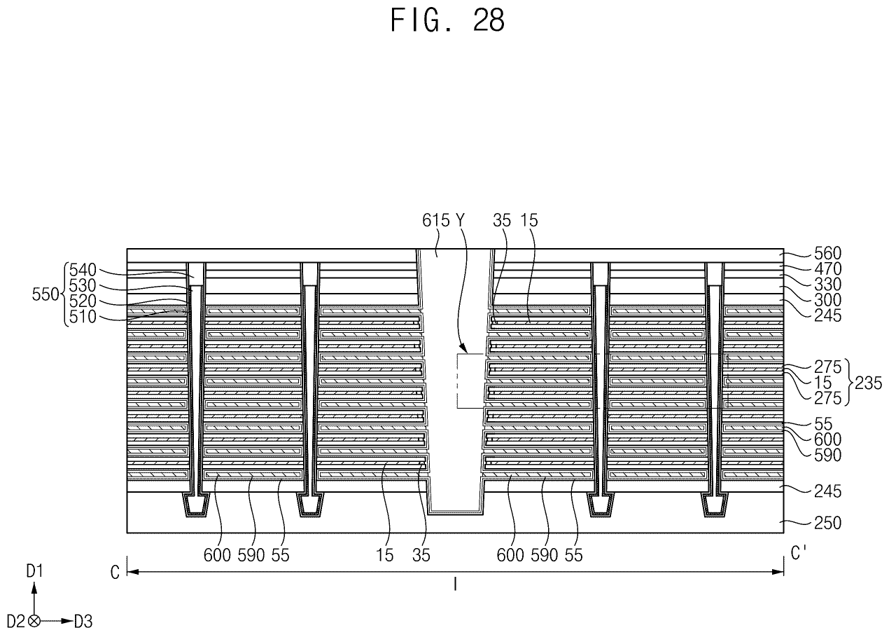

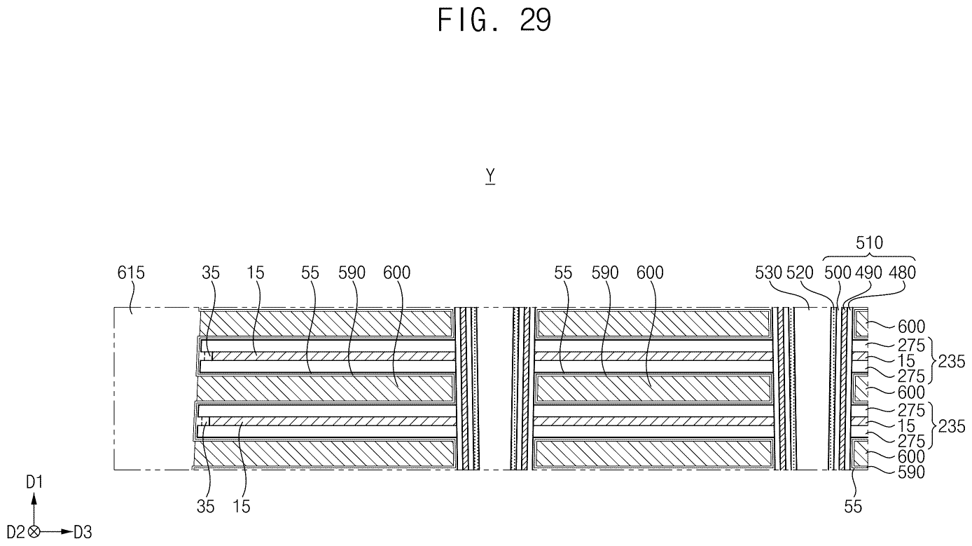

FIGS. 10 to 38 are plan views and cross-sectional views illustrating a method of manufacturing a vertical memory device in accordance with example embodiments.

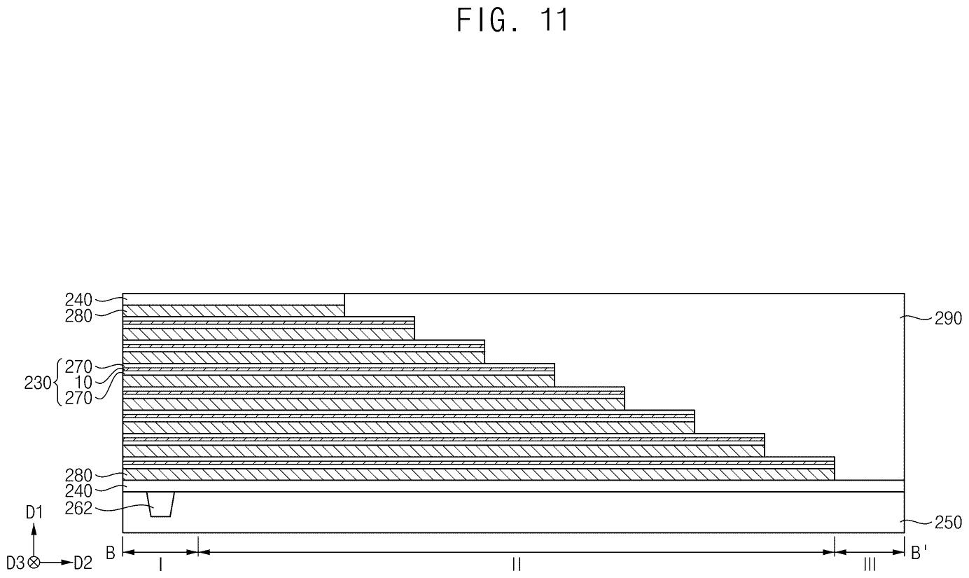

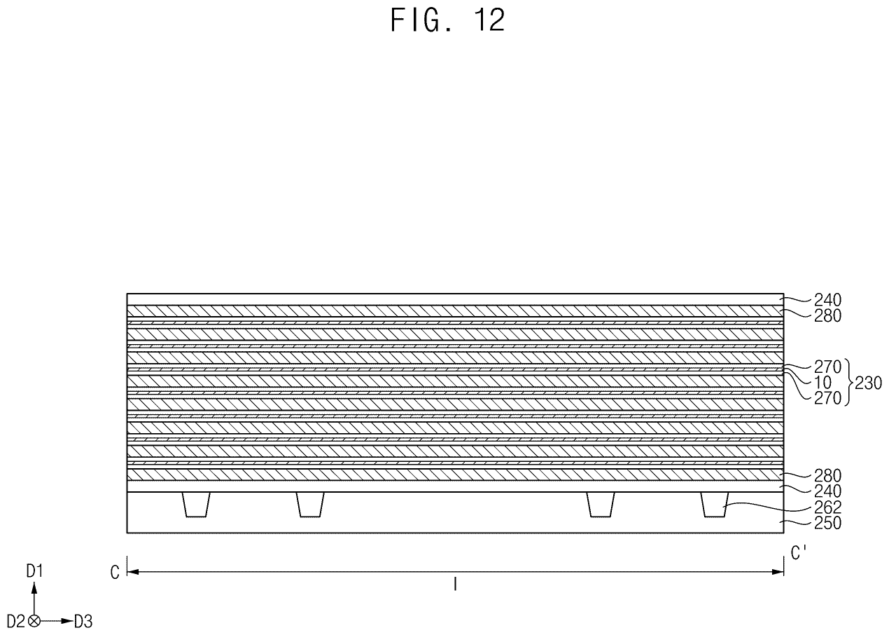

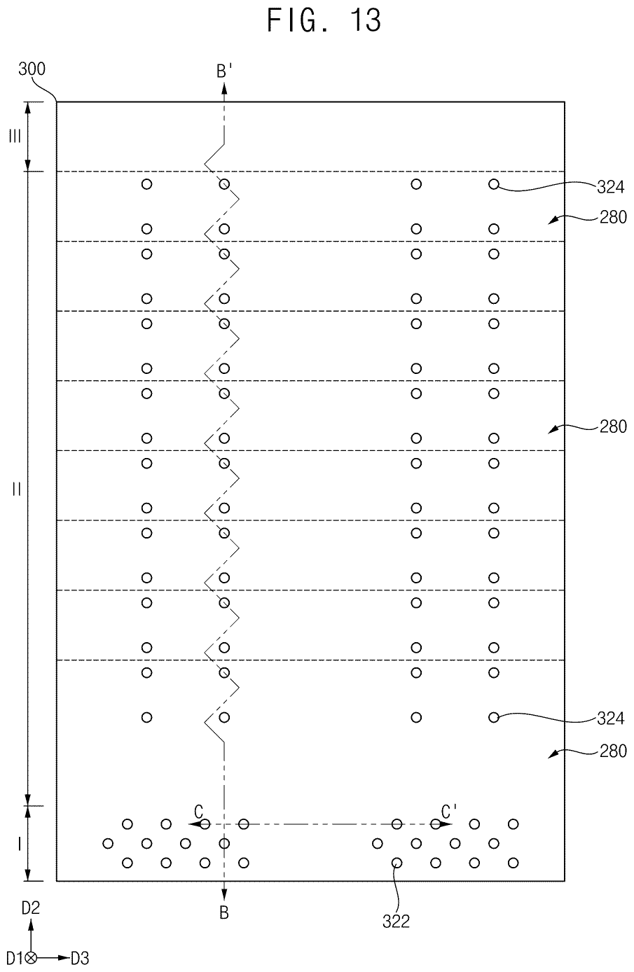

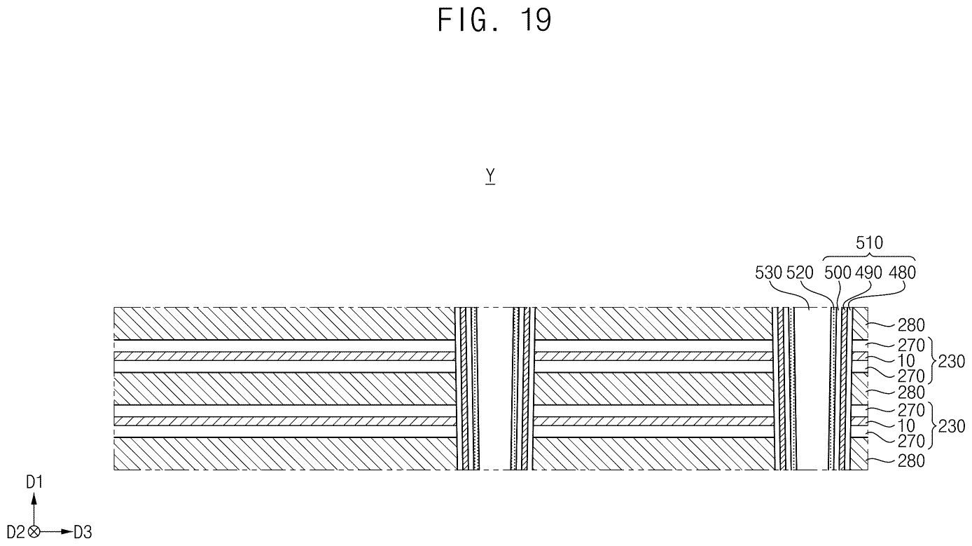

Particularly, FIGS. 13, 16, 20, 26 and 30 are the plan views, and FIGS. 10, 31-32 and 34-38 are cross-sectional views taken along lines A-A′ of corresponding plan views, respectively, FIGS. 11, 14, 17 and 27 are cross-sectional views taken along lines B-B′ of corresponding plan views, respectively, FIGS. 12, 15, 18, 21, 28 and 33 are cross-sectional views taken along lines C-C′ of corresponding plan views, respectively, and FIGS. 19, 22-25 and 29 are enlarged cross-sectional views of region Y corresponding cross-sectional views, respectively. FIGS. 7 to 35 are drawings of region X of FIG. 1.

Referring to FIGS. 10 to 12, first and second sacrificial pattern 262 and 266 may be formed through an upper portion of a second substrate 250, a first insulation layer 240 may be formed on the second substrate 250 and the first and second sacrificial patterns 262 and 266, a third sacrificial layer 280 and a second insulation layer structure 230 may be alternately and repeatedly stacked on the first insulation layer 240 in the first direction D1, and an additional first insulation layer 240 may be formed on an uppermost one of the third sacrificial layers 280.

Thus, a mold layer including the first insulation layers 240, the second insulation layer structures 230 and the third sacrificial layers 280 may be formed.

The second substrate 250 may include first, second and third regions I, II and III. In example embodiments, the second region II may surround the first region I or may be disposed at each of opposite sides in the second direction D2, and the third region III may surround the first and second regions I and II.

The second substrate 250 may include a semiconductor material, e.g., silicon, germanium, silicon-germanium, etc., or a III-V group compound semiconductor, e.g., GaP, GaAs, GaSb, etc. In example embodiments, the second substrate 250 may be a silicon-on-insulator (SOI) substrate or a germanium-on-insulator (GOI) substrate.

In example embodiments, a plurality of first sacrificial patterns 262 may be formed to be spaced apart from each other in each of the second and third directions D2 and D3 in the first region I of the second substrate 250, and a plurality of second sacrificial patterns 266 may be formed to be spaced apart from each other in each of the second and third directions D2 and D3 in the third region III of the second substrate 250.

Each of the first and second sacrificial patterns 262 and 266 may include a metal, e.g., tungsten, or polysilicon. The first insulation layer 240 may include an oxide, e.g., silicon oxide, and the third sacrificial layer 280 may include a material having an etching selectivity with respect to the first insulation layer 240, e.g., an insulating nitride such as silicon nitride. In some embodiments, the third sacrificial layer 280 may have a thickness in the first direction D1 in a range of about 20 nm to about 36 nm.

In example embodiments, the second insulation layer structure 230 may include a second insulation layer 270, a horizontal charge storage layer 10 and the second insulation layer 270 sequentially stacked in the first direction D1. Each of the second insulation layers 270 may include an oxide, e.g., silicon oxide, and the horizontal charge storage layer 10 may include an insulating nitride, e.g., silicon nitride or a metal oxide, e.g., hafnium zinc oxide.

A photoresist pattern partially covering an upper one of the first insulation layers 240 may be formed, and the upper one of the first insulation layers 240 and an uppermost one of the third sacrificial layers 280 may be etched using the photoresist pattern as an etching mask. Thus, a portion of an uppermost one of the second insulation layer structures 230 may be exposed.

After performing a trimming process for reducing an area of the photoresist pattern, the upper one of the first insulation layers 240, the uppermost one of the third sacrificial layers 280, the uppermost one of the second insulation layer structures 230, and one of the third sacrificial layers 280 directly under the uppermost one of the second insulation layer structures 230 may be etched by an etching process using the reduced photoresist pattern as an etching mask.

The trimming process and the etching process may be repeatedly performed to form a mold having a staircase shape and including a plurality of step layers each of which may include a single third sacrificial layer 280 and a single second insulation layer structure 230 sequentially stacked, and an uppermost step layer including the uppermost one of the third sacrificial layers 280 and the upper one of the first insulation layers 240. The mold may further include a single first insulation layer 240 under a lowermost step layer.

Hereinafter, the “step layer” may refer to all portions of the third sacrificial layer 280 and the second insulation layer structure 230 at the same level or all portions of the third sacrificial layer 280 and the upper one of the first insulation layers 240, which may include an unexposed portion as well as an exposed portion, and a “step” may refer to only the exposed portion of the “step layer.” In example embodiments, the steps may be arranged in the second direction D2. Alternatively, the steps may be arranged in the third direction D3.

A twelfth insulating interlayer 290 may be formed on the second substrate 250 to cover the mold, and a planarization process may be performed on the twelfth insulating interlayer 290 until an upper surface of the upper one of the first insulation layers 310 is exposed. Thus, a sidewall of the mold may be covered by the twelfth insulating interlayer 290.

In example embodiments, the planarization process may include a chemical mechanical polishing (CMP) process and/or an etch back process.

Referring to FIGS. 10 to 12, an eleventh insulating interlayer 300 may be formed on the upper one of the first insulation layers 240 and the twelfth insulating interlayer 290, and a first hole extending through the eleventh insulating interlayer 300 and the mold to expose an upper surface of the first sacrificial pattern 262 and a second hole extending through the eleventh and twelfth insulating interlayers 300 and 290 and a portion of the mold to expose an upper surface of the second substrate 250 may be formed.

In example embodiments, a plurality of first holes may be formed to be spaced apart from each other in each of the second and third directions D2 and D2 on the first region I of the second substrate 250, and a plurality of second holes may be formed to be spaced apart from each other in each of the second and third directions D2 and D3 on the second region II of the second substrate 250.

A width of a bottom of the first hole may be smaller than a width of an upper surface of the first sacrificial pattern 262 exposed by the first hole.

The first sacrificial pattern 262 exposed by the first hole may be removed so that the first hole may be enlarged downwardly in the first direction D1 to expose an upper portion of the second substrate 250.

A fourth sacrificial layer may be formed on the second substrate 250 and the eleventh insulating interlayer 300 to fill the first and second holes, and a planarization process may be performed on the fourth sacrificial layer until an upper surface of the eleventh insulating interlayer 300 is exposed to form first and second sacrificial pillars 322 and 324 in the first and second holes, respectively. The fourth sacrificial layer may include an insulating material containing carbon, e.g., silicon carbonitride.

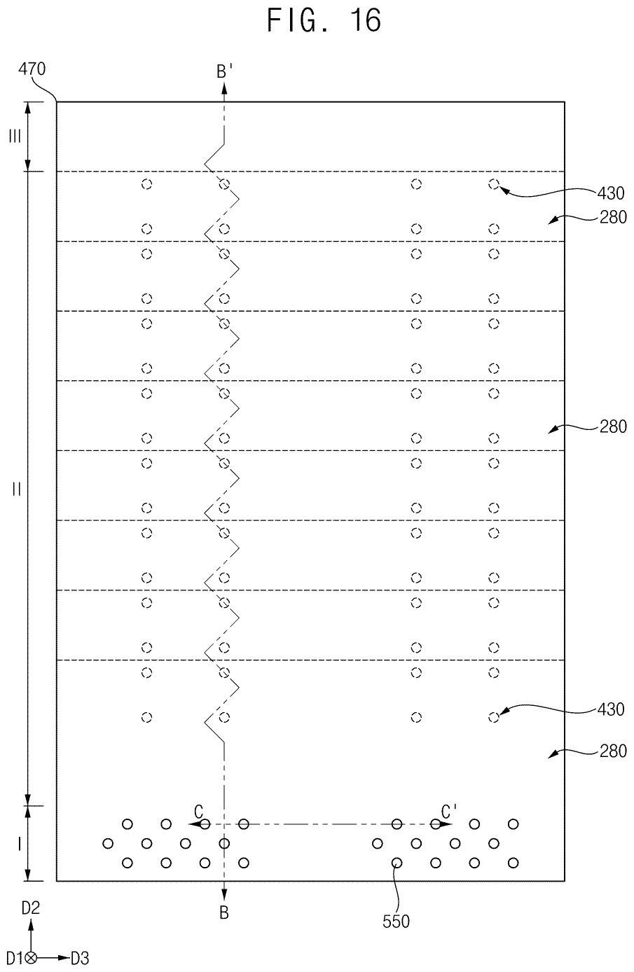

Referring to FIGS. 16 to 19, a tenth insulating interlayer 330 may be formed on the first and second sacrificial pillars 322 and 324 and the eleventh insulating interlayer 300, a third hole may be formed through the tenth insulating interlayer 330 to expose an upper surface of the second sacrificial pillar 324, the second sacrificial pillar 324 exposed by the third hole may be removed to enlarge the third hole downwardly in the first direction D1, and a support structure 430 may be formed in the third hole.

In example embodiments, the second sacrificial pillar may be removed by, e.g., an ashing process.

A ninth insulating interlayer 470 may be formed on the support structure 430 and the tenth insulating interlayer 330, a fourth hole may be formed through the ninth and tenth insulating interlayers 470 and 330 to expose an upper surface of the first sacrificial pillar 322, the first sacrificial pillar 322 exposed by the fourth hole may be removed to enlarge the fourth hole downwardly in the first direction D1, and a memory channel structure 550 may be formed in the fourth hole.

In example embodiments, the first sacrificial pillar 322 may be removed by an ashing process.

In example embodiments, the fourth hole may include a lower portion in the upper portion of the second substrate 250, and an upper portion extending through the mold and the ninth to eleventh insulating interlayers 470, 330 and 300. A width of a top of the lower portion of the fourth hole may be greater than a width of a bottom of the upper portion of the fourth hole. The memory channel structure 550 may include a lower portion and an upper portion corresponding to the shape of the fourth hole. A width of an upper surface of the lower portion of the memory channel structure 550 may be greater than a width of a lower surface of the upper portion of the memory channel structure 550.

The memory channel structure 550 may be formed by following processes.

A vertical charge storage layer structure and a channel layer may be sequentially formed on a sidewall and a bottom of the fourth hole and an upper surface of the ninth insulating interlayer 470, a filling layer may be formed on the channel layer to fill the fourth hole, and a planarization process may be performed on the filling layer, the channel layer and the vertical charge storage layer structure until the upper surface of the ninth insulating interlayer 470 is exposed to form a filling pattern 530, a channel 520 and a vertical charge storage structure 510 in the fourth hole.

The vertical charge storage layer structure may include a first blocking layer, a vertical charge storage layer and a tunnel insulation layer, and the vertical charge storage structure 510 may include a first blocking pattern 480, a vertical charge storage pattern 490 and a tunnel insulation pattern 500 sequentially stacked on the sidewall and the bottom of the fourth hole.

Upper portions of the filling pattern 530 and the channel 520 may be removed to form a first recess, a first capping layer may be formed on the filling pattern 530, the channel 520, the vertical charge storage structure 510 and the ninth insulating interlayer 470 to fill the first recess, and a planarization process may be performed on the first capping layer until an upper surface of the ninth insulating interlayer 470 is exposed to form a first capping pattern 540 disposed on upper surfaces of the filling pattern 530 and the channel 520 and contacting an upper sidewall of the vertical charge storage structure 510.

The filling pattern 530 extending in the first direction D1, the channel 520 covering a sidewall and a lower surface of the filling pattern 530, the first capping pattern 540 on the upper surfaces of the filling pattern 530 and the channel 520, and the vertical charge storage structure 510 covering a sidewall and a lower surface of the channel 520 and a sidewall of the first capping pattern 540 may collectively form a memory channel structure 550.

In the drawing, an upper surface of the memory channel structure 550 is higher than an upper surface of the support structure 430, however, the present disclosure is not limited thereto. For example, the upper surface of the memory channel structure 550 may be lower than the upper surface of the support structure 430.

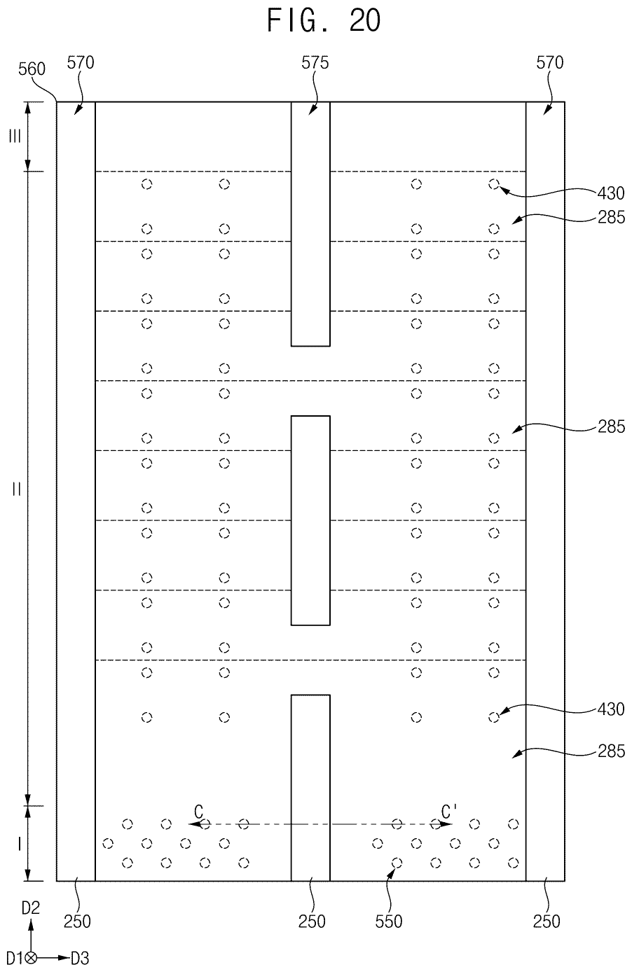

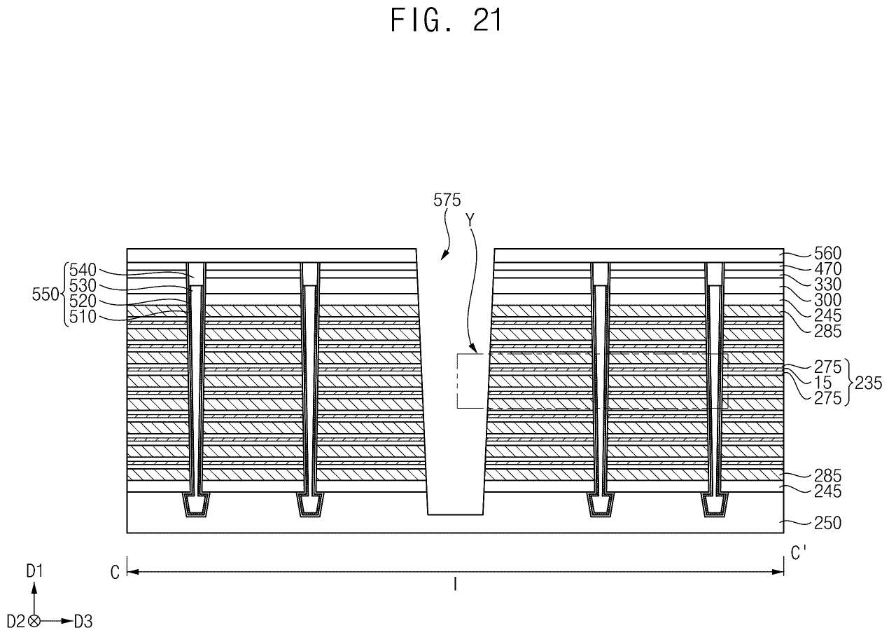

Referring to FIGS. 20 and 21, an eighth insulating interlayer 560 may be formed on the ninth insulating interlayer 470 and the memory channel structure 550, and an etching process may be performed to form first and second openings 570 and 575 extending through the eighth to twelfth insulating interlayers 560, 470, 330, 300 and 290 and the mold to expose the upper surface of the second substrate 250.

In example embodiments, the first opening 570 may extend in the second direction D2 on the first and second regions I and II of the second substrate 250 to both ends in the second direction D2 of the mold, and a plurality of first openings 570 may be formed to be spaced apart from each other in the third direction D3. Thus, the mold may be divided into a plurality of parts by the first openings 570 on the first and second regions I and II of the second substrate 250, and the first insulation layer 240, the third sacrificial layer 280 and the second insulation layer structure 230 included in the mold may be divided into first insulation patterns 245, third sacrificial patterns 285 and second insulation structures 235 each of which may extend in the second direction D2. Each of the second insulation structures 235 may include second insulation patterns 275 and a horizontal charge storage pattern 15 between the second insulation patterns 275.

In example embodiments, the second opening 575 may be formed between ones of the first openings 570 neighboring in the third direction D3 on the first and second regions I and II of the second substrate 250, and a plurality of second openings 575 may be formed to be spaced apart from each other in the second direction D2.

When the mold is divided into the plurality of parts each extending in the second direction D2 by the etching process for forming the first and second openings 570 and 575, the molds may not collapse by the support structure 430 and the memory channel structure 550 extending through each of the molds.

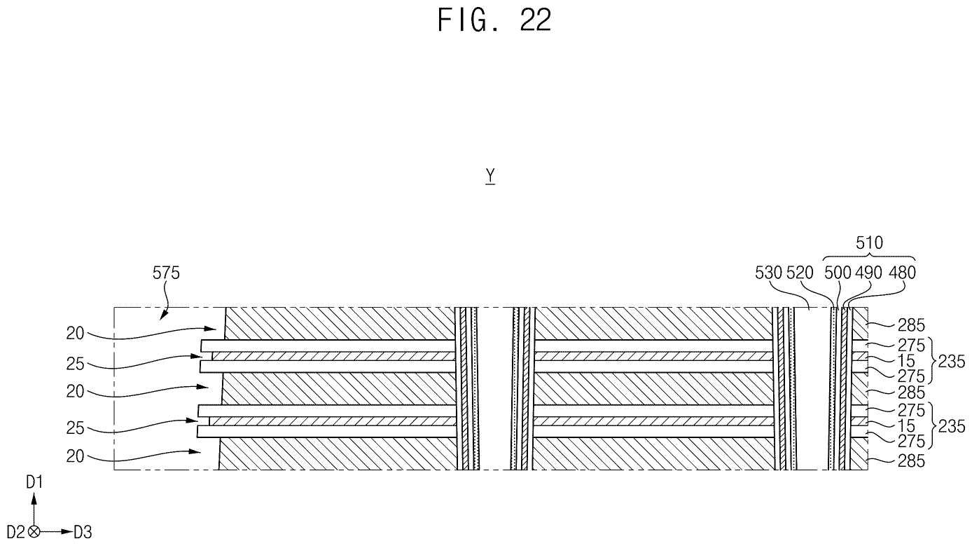

Referring to FIG. 22, portions of the third sacrificial pattern 285 and the horizontal charge storage pattern 15 adjacent to the first and second openings 570 and 575 in the third direction D3 may be removed by an etching process to form second and third recesses 20 and 25, respectively.

The etching process may be performed by a wet etching process using, e.g., H₃PO₄ or a dry etching process, and due to a micro loading effect, the horizontal charge storage pattern 15 having a relatively small thickness in the first direction D1 may be etched less than the third sacrificial pattern 285 having a relatively large thickness in the first direction D1. Thus, a depth in the third direction D3 of the third recess 25 may be less than a depth in the third direction D3 of the second recess 20.

In some embodiments, a width in the first direction D1 of the second recess 20 may be in a range of about 20 nm to about 36 nm.

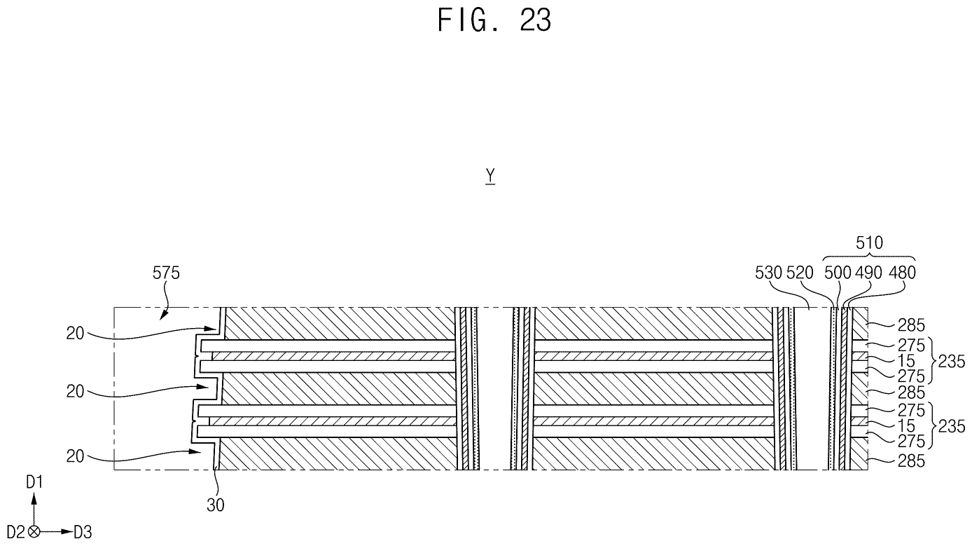

Referring to FIG. 23, a second capping layer 30 may be formed on inner walls of the first and second openings 570 and 575 and the second and third recesses 20 and 25, the upper surface of the second substrate 250 and an upper surface of the eighth insulating interlayer 560.

In example embodiments, the second capping layer 30 may be formed by an atomic layer deposition (ALD) process, and may include an oxide, e.g., silicon oxide or a low-k dielectric material.

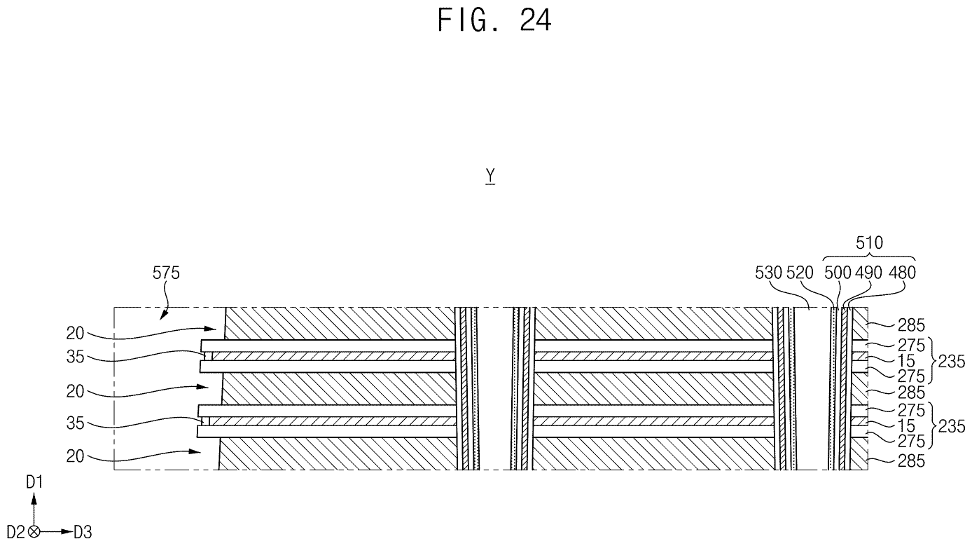

Referring to FIG. 24, a wet etching process using, e.g., HF or a dry etching process may be performed to partially remove the second capping layer 30.

Thus, a portion of the second capping layer 30 in the third recess 25 may remain as a second capping pattern 35, and other portions of the second capping layer 30 may be removed so that the second recess 20 may be formed again.

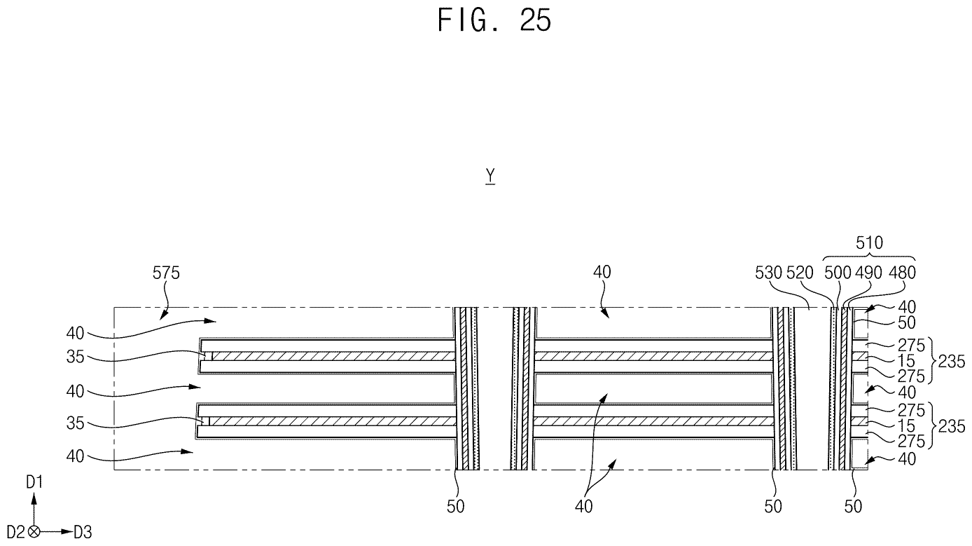

Referring to FIG. 25, a wet etching process using, e.g., H₃PO₄ or H₂SO₄ may be performed to remove the third sacrificial pattern 285 to form a gap 40.

The wet etching process may be performed through the first and second openings 570 and 575 and the second recess 20, and a portion of the third sacrificial pattern 285 between the first and second openings 570 and 575 by an etchant respectively introduced from both directions through the first and second openings 570 and 575 on the first and second regions I and II of the second substrate 250.

The horizontal charge storage pattern 15 may be covered by the second capping pattern 35, and thus may not be removed by the wet etching process but remain.

A spacer layer 50 may be formed on the inner walls of the first and second openings 570 and 575, an inner wall of the gap 40, a sidewall of the second capping pattern 35, the upper surface of the second substrate 250 and the upper surface of the eighth insulating interlayer 560.

In example embodiments, the spacer layer 50 may be formed by an atomic layer deposition (ALD) process, and may include an oxide, e.g., silicon oxide or a low-k dielectric material. In some embodiments, the spacer layer 50 may have a thickness of about 1.5 nm to about 2.5 nm, and thus a width in the first direction D1 of other portion of the gap 40 partially filled with the spacer layer 50 may be in a range of about 15 nm to about 33 nm.

In some embodiments, the spacer layer 50 may be merged to the second capping pattern 35 so as not be distinguished therefrom. Alternatively, the spacer layer 50 may be distinguished from the second capping pattern 35.

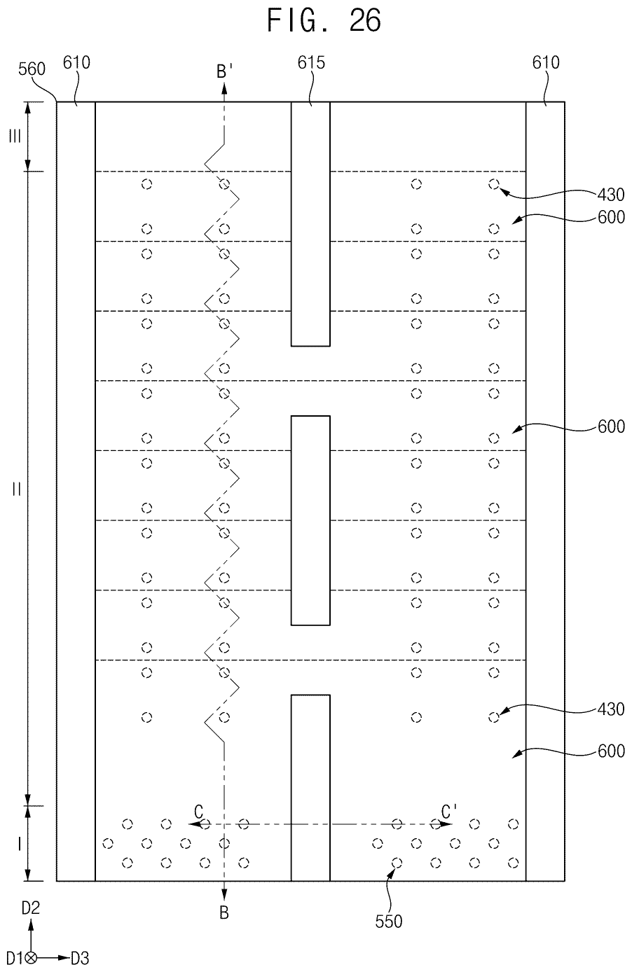

Referring to FIGS. 26 to 29, a second blocking layer may be formed on the spacer layer 50, and a second gate electrode layer may be formed on the second blocking layer to fill the first and second openings 570 and 575.

The second gate electrode layer may be partially removed by, e.g., a wet etching process to form a second gate electrode 600 in the gap 40. In some embodiments, the second gate electrode 600 may have a thickness in the first direction D1 in a range of about 15 nm to about 33 nm.

In example embodiments, the second gate electrode 600 may extend in the second direction D2, and a plurality of second gate electrodes 600 may be formed at a plurality of levels, respectively, to form a second gate electrode structure. In example embodiments, a plurality of second gate electrode structures may be formed in the third direction D3, which may be separated from each other by the first openings 570.

As described above, each of the second openings 575 may not continuously extend in the second direction D2 on the first and second regions I and II of the second substrate 250 but a plurality of second openings 575 may be spaced apart from each other in the second direction D2, so that the second gate electrode structure may not be separated from each other in the third direction D3 by the second openings 575.

A division layer may be formed on the second gate electrode 600 and the second blocking layer to fill the first and second openings 570 and 575, and a planarization process may be performed on the division layer, the second blocking layer and the spacer layer 50 until an upper surface of the eighth insulating interlayer 560 is exposed.

Thus, first and second division patterns 610 and 615 may be formed in the first and second openings 570 and 575, respectively, and the second blocking layer and the spacer layer 50 may be transformed into a second blocking pattern 590 and a spacer 55, respectively.

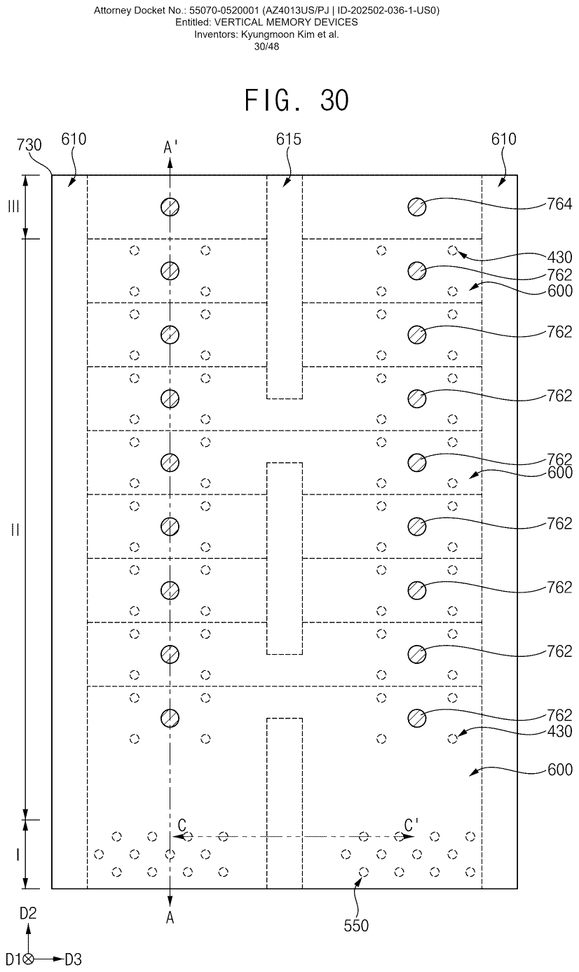

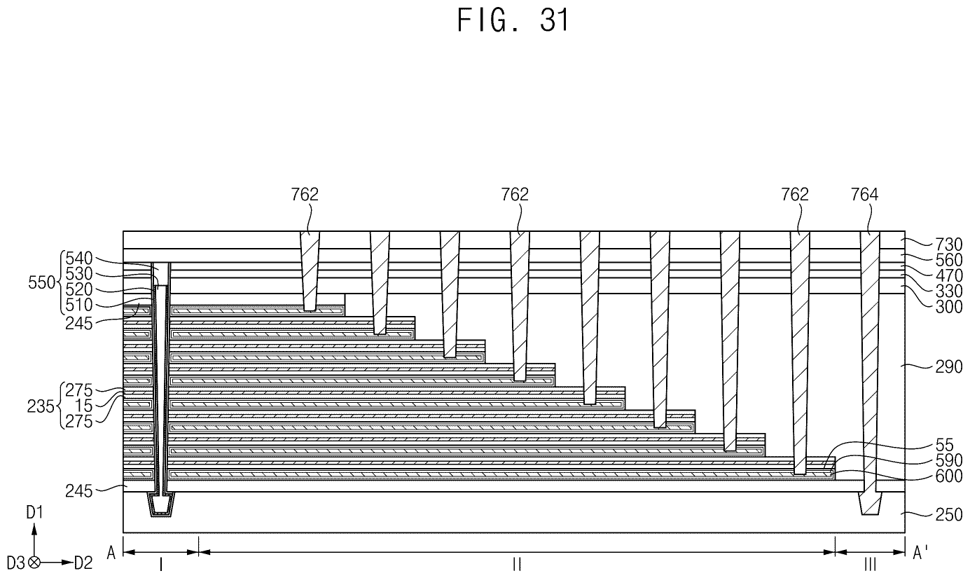

Referring to FIGS. 30 and 31, a seventh insulating interlayer 730 may be formed on the first and second division patterns 610 and 615, the eighth insulating interlayer 560, the second blocking pattern 590 and the spacer 55.

A fifth hole may be formed on the second region II of the second substrate 250 to extend through the seventh to twelfth insulating interlayers 730, 560, 470, 330, 300 and 290, the spacer 55 and the second blocking pattern 590 to expose an upper surface of an end portion in the second direction D2 of each of the second gate electrodes 600, and a second contact plug 762 may be formed in the fifth hole.

Additionally, a sixth hole may be formed on the third region III to extend through the seventh to twelfth insulating interlayers 730, 560, 470, 330, 300 and 290 and a lower one of the first insulation patterns 245 to expose an upper surface of the second sacrificial pattern 266, the second sacrificial pattern 266 exposed by the sixth hole may be removed to enlarge the sixth hole downwardly in the first direction D1, and a through via 764 may be formed in the sixth hole.

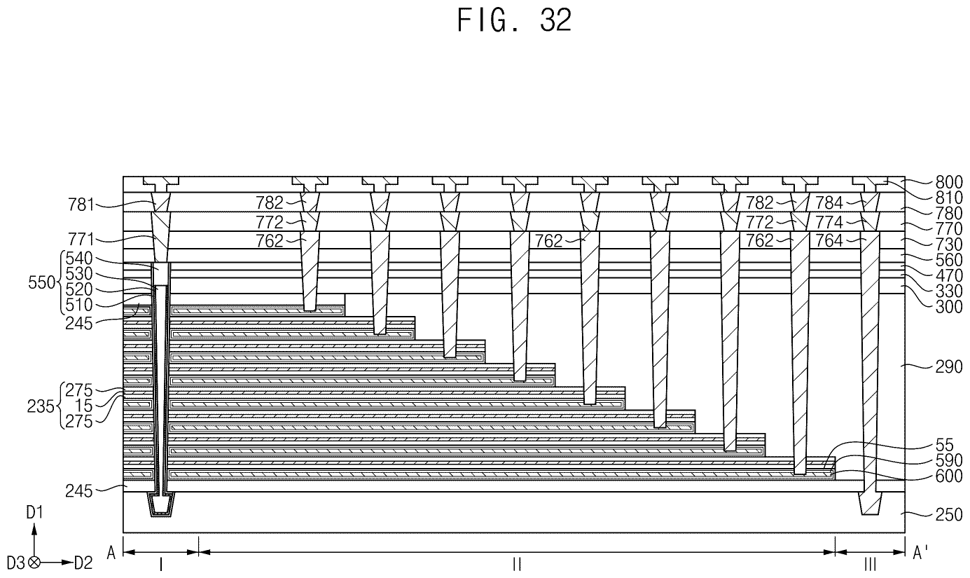

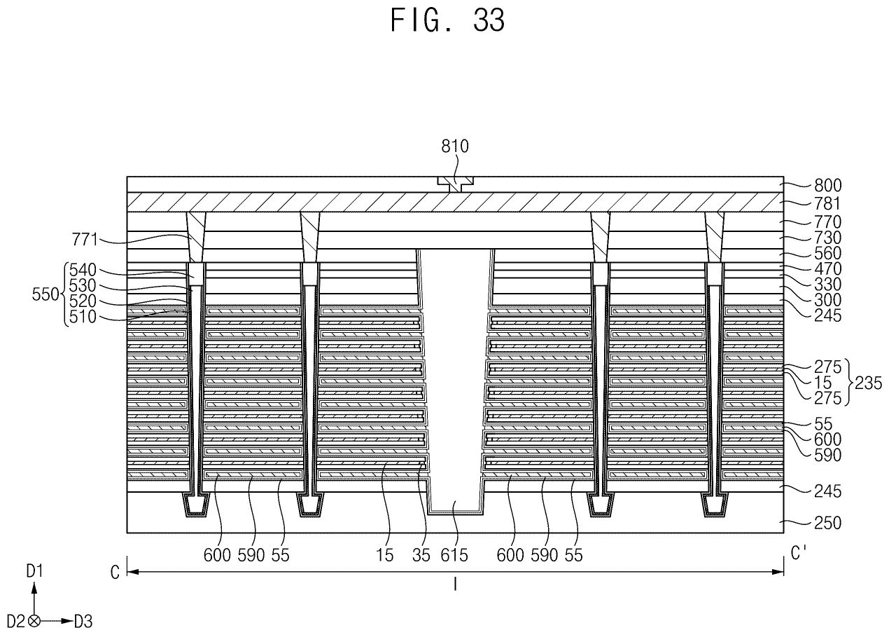

Referring to FIGS. 32 and 33, a sixth insulating interlayer 770 may be formed on the seventh insulating interlayer 730, the second contact plug 762 and the through via 764, and a second via 771 extending through the sixth to eighth insulating interlayers 770, 730 and 560 to contact an upper surface of the memory channel structure 550, a third via 772 extending through the sixth insulating interlayer 770 to contact an upper surface of the second contact plug 762, and a fourth via 774 extending through the sixth insulating interlayer 770 to contact an upper surface of the through via 765 may be formed.

A fifth insulating interlayer 780 may be formed on the sixth insulating interlayer 770 and the second to fourth vias 771, 772 and 774, and third to fifth wirings 781, 782 and 784 extending through the fifth insulating interlayer 780 to contact upper surfaces of the second to fourth vias 771, 772 and 774, respectively, may be formed. In example embodiments, the third wiring 781 may extend in the third direction D3 on the first and second regions I and II of the second substrate 250, and a plurality of third wirings 781 may be formed to be spaced apart from each other in the second direction D2.

A second bonding layer 800 may be formed on the fifth insulating interlayer 780 and the third to fifth wirings 781, 782 and 784, and second bonding pads 810 may be formed through the second bonding layer 800 to contact upper surfaces of the third to fifth wirings 781, 782 and 784, respectively.

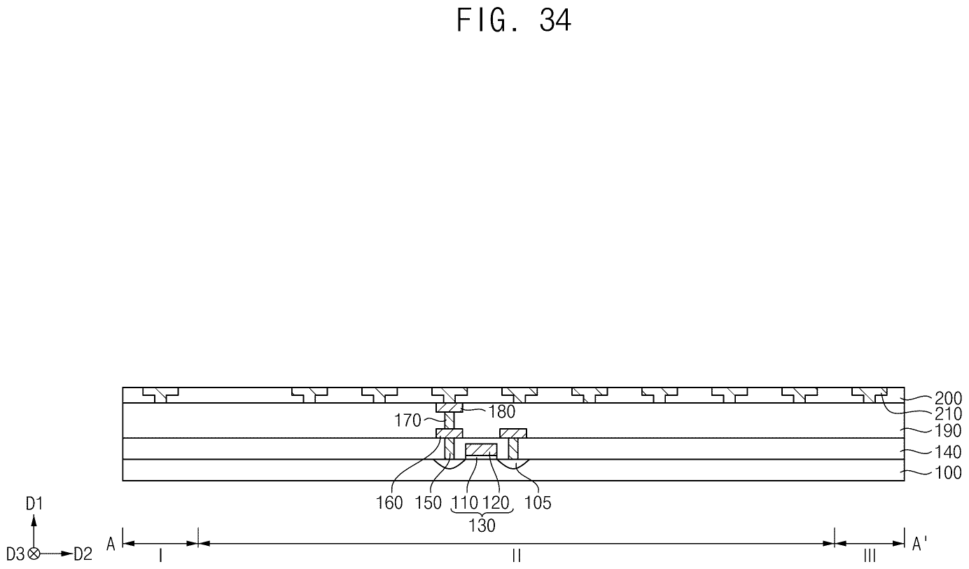

Referring to FIG. 34, a lower circuit pattern may be formed on a first substrate 100, and first and second insulating interlayers 140 and 190 may be sequentially formed on the first substrate 100 to cover the lower circuit pattern.

Each element of the lower circuit pattern may be formed by a subtractive patterning process or a damascene process.

A first bonding layer 200 may be formed on the second insulating interlayer 190, and first bonding pads 210 may be formed through the first bonding layer 200 to contact corresponding elements of the lower circuit pattern.

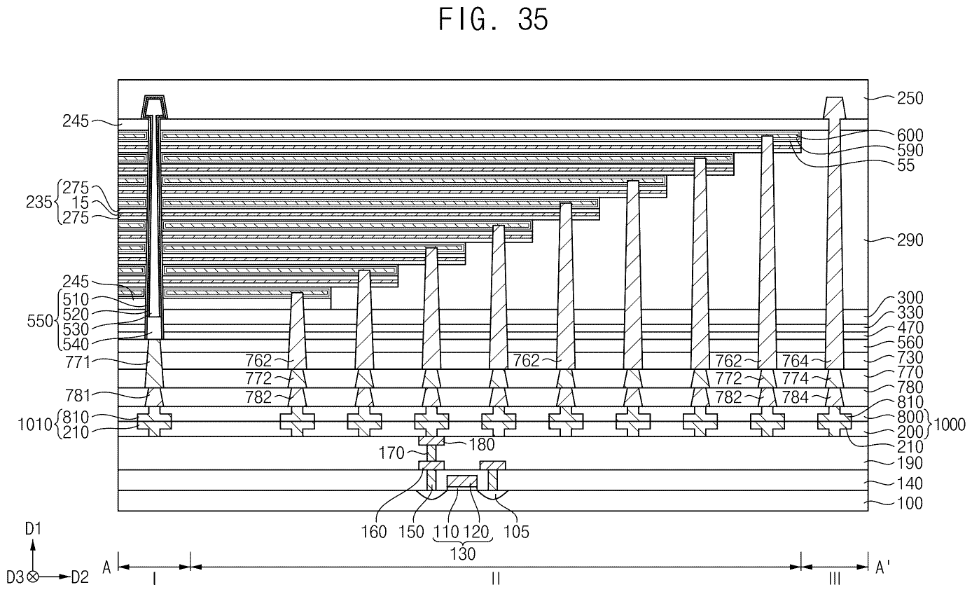

Referring to FIG. 35, the second substrate 250 may be flipped, and the first and second substrates 100 and 250 may be bonded with each other by bonding the first and second bonding layers 200 and 800 to each other.

The first and second bonding layers 200 and 800 contacting each other may form a bonding layer structure 1000, and the first and second bonding pads 210 and 810 may contact each other to form a bonding pad structure 1010.

Hereinafter, descriptions are given based on a state in which upper and lower portions of various structures on the second substrate 250 are inverted.

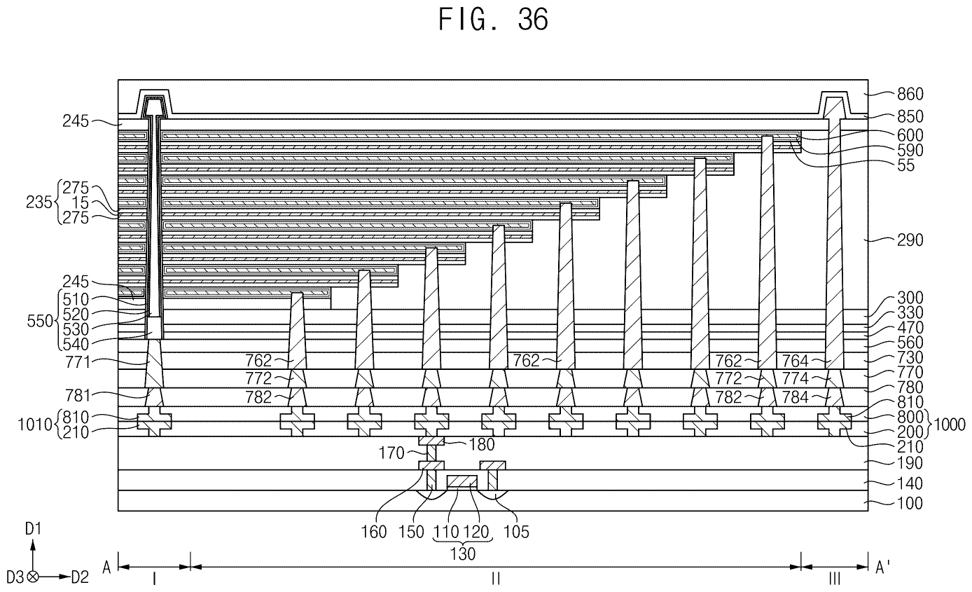

Referring to FIG. 36, the second substrate 250 may be removed to expose a surface of a portion of the vertical charge storage structure 510 of an upper portion of the memory channel structure 550 and a surface of an upper portion of the through via 764, an etch stop layer 850 may be formed on the surface of the portion of the vertical charge storage structure 510 of the upper portion of the memory channel structure 550 and the surface of the upper portion of the through via 764, and a planarization process may be performed.

As the second substrate 250 is removed, hereinafter, spaces overlapping the first to third regions I, II and III defined in the second substrate 250 in the first direction D1 may be defined as the first to third regions I, II and III, respectively.

The etch stop layer 850 may include an insulating nitride, e.g., silicon nitride, and the fourth insulating interlayer 860 may include an oxide, e.g., silicon oxide.

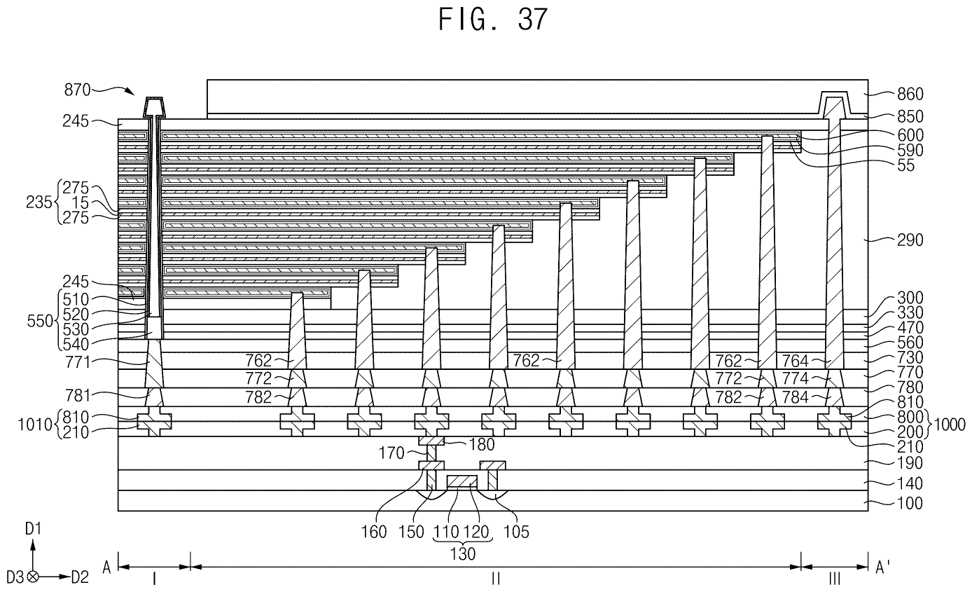

Referring to FIG. 37, a third opening 870 may be formed through portions of the fourth insulating interlayer 860 and the etch stop layer 850 in the first region I to expose a surface of the portion of the vertical charge storage structure 510 of the upper portion of the memory channel structure 550 and an upper surface of a portion of the upper one of the first insulation patterns 245 adjacent thereto.

The portion of the vertical charge storage structure 510 of the upper portion of the memory channel structure 550 exposed by the third opening 870 may be removed to expose a surface of a portion of the channel 520 of the upper portion of the memory channel structure 550 may be exposed.

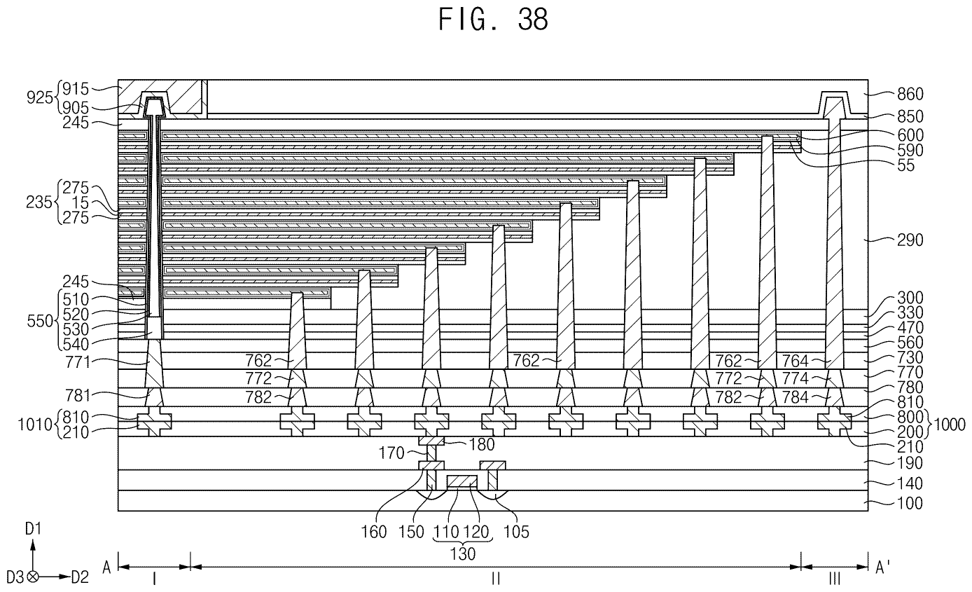

Referring to FIG. 38, a common source plate (CSP) layer structure may be formed on the surface of the portion of the channel 520 of the upper portion of the memory channel structure 550 and the upper surface of the upper one of the first insulation patterns 245 exposed by the third opening 870, a sidewall of the third opening 870 and an upper surface of the fourth insulating interlayer 860, and a planarization process may be performed on the CSP layer structure until the upper surface of the fourth insulating interlayer 860 is exposed to form a CSP structure 925 in the first region I.

In example embodiments, the CSP structure 925 may include a barrier pattern 905 and a conductive pattern 915 sequentially stacked.

A third division pattern may be formed through the CSP structure 925, the spacer 55 and the second blocking pattern 590 to contact an upper surface of the first division pattern 610.

Referring to FIGS. 1 to 6 again, a third insulating interlayer 940 may be formed on the CSP structure 925, the third division pattern and the fourth insulating interlayer 860, and a seventh hole extending through the third insulating interlayer 940 to expose an upper surface of the CSP structure 925 and an eighth hole extending through the third and fourth insulating interlayers 940 and 860 and the etch stop layer 850 to expose an upper surface of the through via 764 may be formed.

Third and fourth contact plugs 942 and 944 may be formed in the seventh and eighth holes, respectively, to manufacture the vertical memory device.

As described above, the portions of the third sacrificial pattern 285 and the horizontal charge storage pattern 15 adjacent to the first and second openings 570 and 575 may be removed to form the second and third recesses 20 and 25, the second capping pattern 35 may be formed in the third recess 25 to cover the horizontal charge storage pattern 15, the third sacrificial pattern 285 may be removed to form the gap 40, the spacer layer 50 and the second blocking layer may be sequentially stacked on the inner wall of the gap 40, the second gate electrode layer may be formed on the second blocking layer to fill the gap 40, the second gate electrode layer may be partially removed to form the second gate electrode 600, the division layer may be formed on the second gate electrode 600 and the second blocking layer to fill the first and second openings 570 and 575, the planarization process may be performed on the division layer, the second blocking layer and the spacer layer so that the first and second division patterns 610 and 615 may be formed in the first and second openings 570 and 575, respectively, and the second blocking layer and the spacer layer 50 may be transformed into the second blocking pattern 590 and the spacer 55, respectively.

Thus, the horizontal charge storage pattern 15 may be formed between neighboring ones of the second gate electrodes 600 in the first direction D1, and the horizontal charge storage pattern 15 may be formed to protrude toward the memory channel structure 550 by a thickness of a portion of the spacer layer 50 in the gap 40 when compared to a portion of the second blocking pattern 590 on the sidewall of the second gate electrode 600.

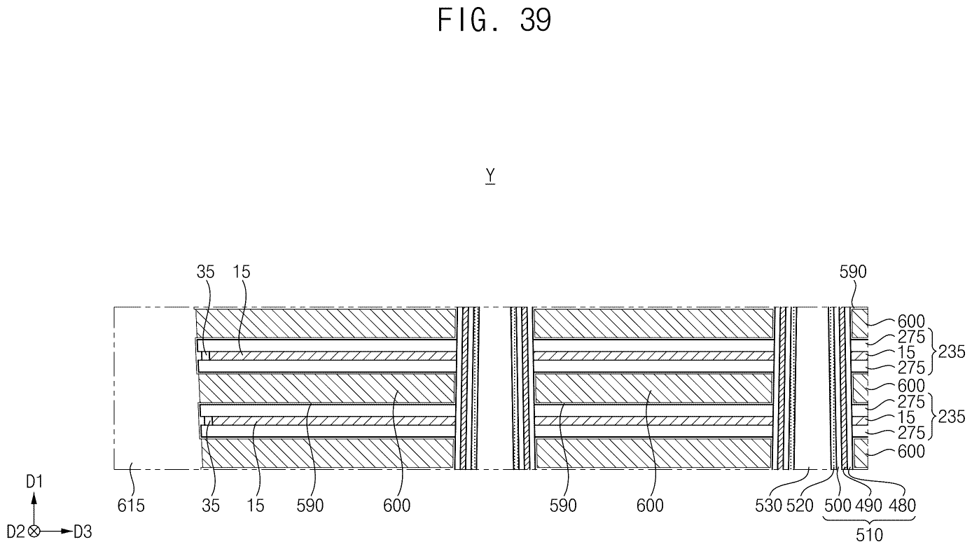

FIGS. 39 to 45 are cross-sectional views illustrating vertical memory devices, respectively, in accordance with example embodiments, which may correspond to FIG. 6.

These vertical memory devices may be substantially the same as or similar to that of FIGS. 1 to 6, except for some elements, e.g., the horizontal charge storage pattern, the second capping pattern, the first insulation pattern, etc., and thus repeated explanations are omitted herein.

Referring to FIG. 39, the vertical memory device may not include the spacer 55.

Thus, the second gate electrode 600 may be spaced apart from the sidewall of the memory channel structure 550, that is, the outer sidewall of the first blocking pattern 480 only by the second blocking pattern 590, and even in this case, a distance from the memory channel structure 550 to the second gate electrode 600 may be greater than a distance from the horizontal charge storage pattern 15 to the memory channel structure 550.

However, a portion of the second blocking pattern 590 on the sidewall of the second gate electrode 600 facing the memory channel structure 550 may also contact the sidewall of the memory channel structure 550 as the horizontal charge storage pattern 15, and thus the horizontal charge storage pattern 15 may not protrude toward the memory channel structure 550 in the horizontal direction when compared to the portion of the second blocking pattern 590 on the sidewall of the second gate electrode 600 facing the memory channel structure 550.

As the vertical memory device does not include the spacer 55, a sidewall of the second capping pattern 35, lower and upper surfaces and a sidewall of the second insulation structure 235 and a sidewall of the memory channel structure 550 may be covered by the second blocking pattern 590.

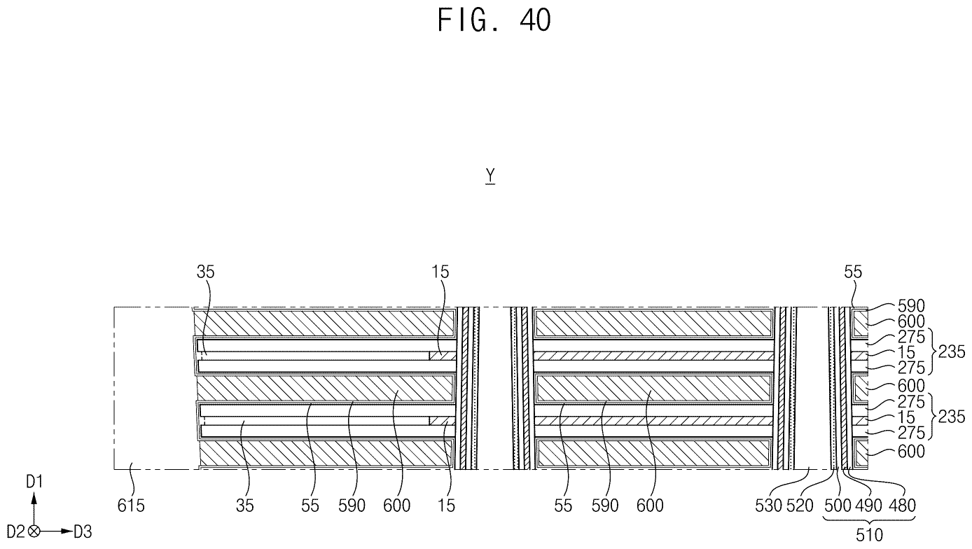

Referring to FIG. 40, an extension length in the third direction D3 of the horizontal charge storage pattern 15 may be less than an extension length in the third direction D3 of the horizontal charge storage pattern 15 included in the vertical memory device of FIGS. 1 to 6.

That is, the horizontal charge storage pattern 15 may surround a first one of the memory channel structure 550 that is closest to each of the first and second division patterns 610 and 615 among the memory channel structures 550 in each of the memory blocks, and may overlap a portion of the second gate electrode 600 adjacent to a sidewall of the first one of the memory channel structure 550, while the horizontal charge storage pattern 15 may not overlap a portion of the second gate electrode 600 spaced apart from the sidewall of the first one of the memory channel structure 550 in the third direction D3.

As described above, electrons may be intensively trapped by a fringing effect at a portion of the horizontal charge storage pattern 15 adjacent to the memory channel structure 550, that is, a protruding portion of the horizontal charge storage pattern 15 protruding toward the memory channel structure 550 relative to the second gate electrode 600. Thus, the extension length of the horizontal charge storage pattern 15 in the third direction D3 may not be as large as the extension length of the second gate electrodes 600 in the third direction D disposed over and under the horizontal charge storage pattern 15, and may have a sufficient effect even if the extension length is sufficient to surround a sidewall of the first one of the memory channel structures 550. In some examples, the sufficient length is predetermined to provide a predetermined level of effect.

A width in the third direction D3 of the second capping pattern 35 contacting an end portion in the third direction D3 of the horizontal charge storage pattern 15 may be greater than a width in the third direction D3 of the second capping pattern 35 included in the vertical memory device of FIGS. 1 to 6.

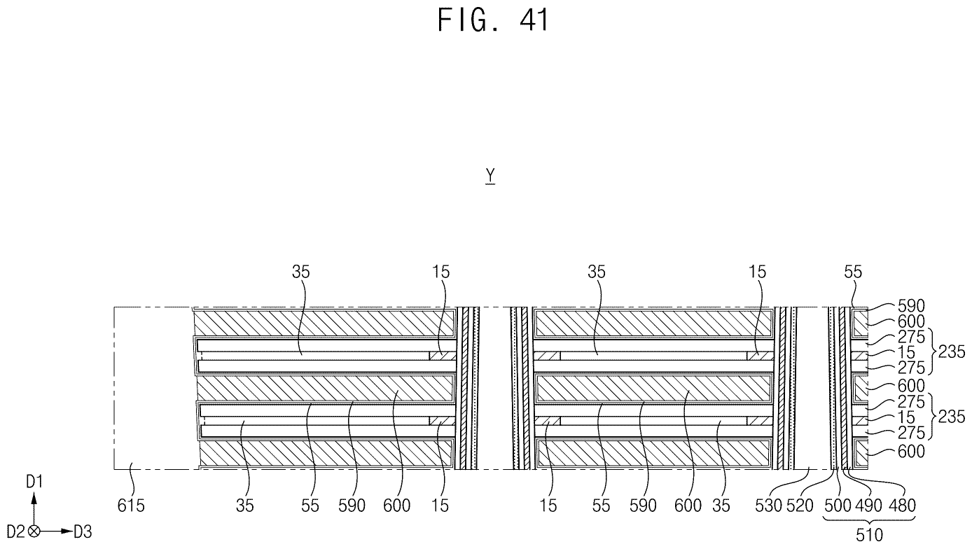

Referring to FIG. 41, the horizontal charge storage pattern 15 may have a ring shape or an annular shape surrounding a sidewall of each of the memory channel structures 550.

Thus, a plurality of horizontal charge storage patterns 15 may be spaced apart from each other in each of the second and third direction D2 and D3.

As described above, the fringing effect may intensively occur between portions of the second gate electrodes 600 adjacent to each of the memory channel structures 550, and thus, even though the horizontal charge storage pattern 15 is disposed between the portions of the second gate electrodes 600 adjacent to each of the memory channel structures 550, a sufficient amount of electrons may be trapped in the horizontal charge storage pattern 15 so that the reduction of the back tunneling phenomenon and the efficiency of the erase operation may be enhanced.

In example embodiments, the second capping pattern 35 may be disposed between the horizontal charge storage patterns 15 at the same level, and between the horizontal charge storage patterns 15 and each of the first and second division patterns 610 and 615.

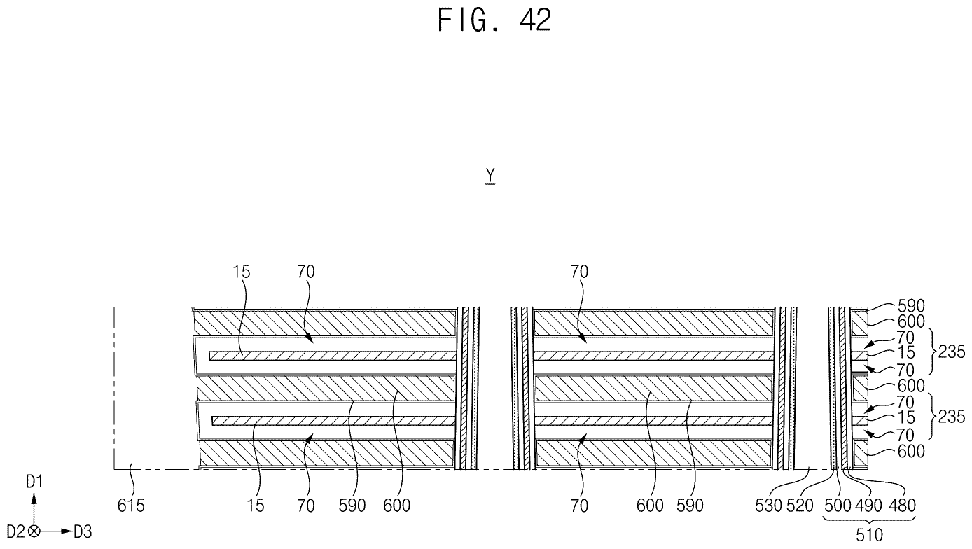

Referring to FIG. 42, the vertical memory device may not include the second insulation pattern 275 and the second capping pattern 35, and may include an air gap 70 surrounding the lower and upper surfaces and opposite sidewalls in the third direction D3 of the horizontal charge storage pattern 15.

Thus, the second insulation structure 235 may include the horizontal charge storage pattern 15 and the air gap 70 surrounding the horizontal charge storage pattern 15. As the second insulation structure 235 includes the air gap 70 instead of the second insulation pattern 275, a parasitic capacitance between ones of the second gate electrodes 600 neighboring in the first direction D1 may be reduced, and an RC delay may be reduced.

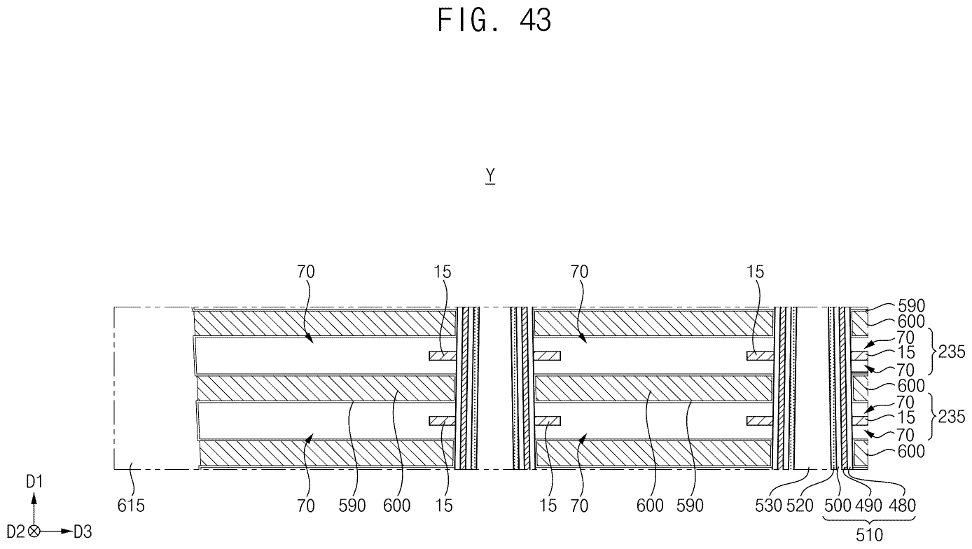

Referring to FIG. 43, as shown in FIG. 41, the horizontal charge storage pattern 15 may have a ring shape or an annular shape surrounding the sidewall of the memory channel structure 550, and as shown in FIG. 42, the second insulation structure 235 may include the horizontal charge storage pattern 15 and the air gap 70 surrounding the horizontal charge storage pattern 15.

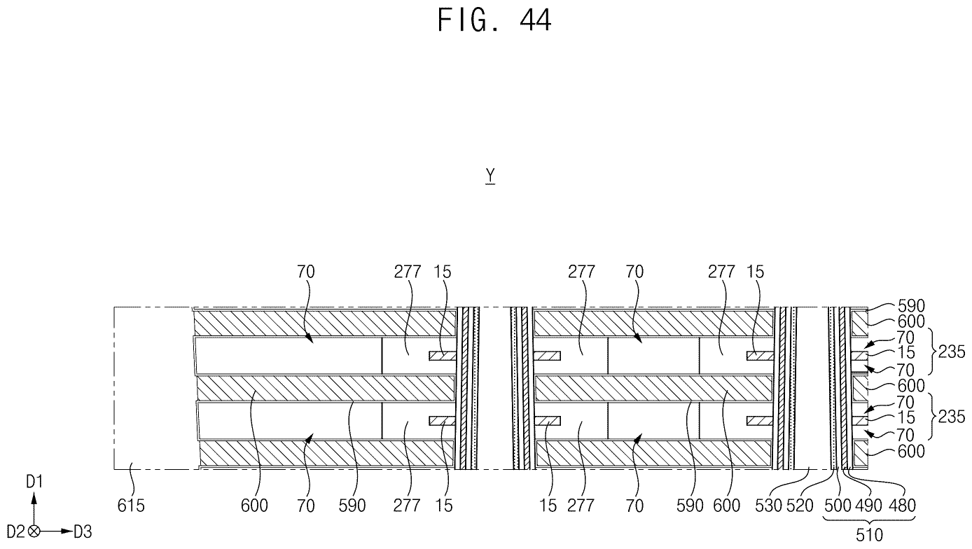

Referring to FIG. 44, the second insulation structure 235 may include the horizontal charge storage pattern 15 having a ring shape or an annular shape surrounding the sidewall of the memory channel structure 550, a third insulation pattern 277 surrounding the lower and upper surfaces and a sidewall of the horizontal charge storage pattern 15, and the air gap 70 between the third insulation patterns 277.

The third insulation pattern 277 may include an oxide, e.g., silicon oxide or a low-k dielectric material.

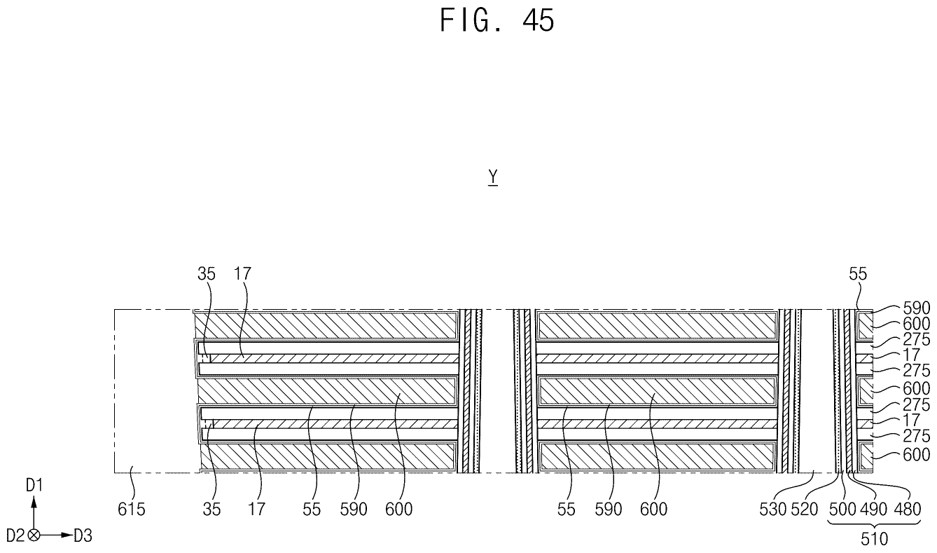

Referring to FIG. 45, a floating gate 17 may be disposed between the second insulation patterns 275 instead of the horizontal charge storage pattern 15.

The floating gate 17 may include a conductive material, e.g., a metal, a metal nitride, a metal silicide, doped polysilicon, etc.

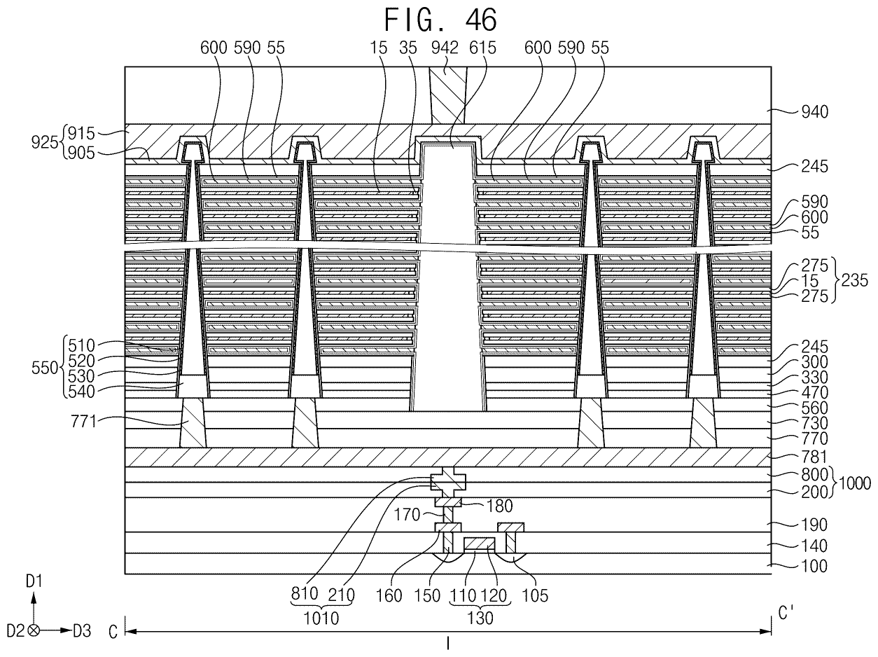

FIGS. 46 to 48 are cross-sectional views illustrating vertical memory devices, respectively, in accordance with example embodiments, which may correspond to FIG. 5.

These vertical memory device may be substantially the same as or similar to that of FIGS. 1 to 6, except for some elements, and thus repeated explanations are omitted herein.

Referring to FIG. 46, a plurality of memory channel structures 550 may be disposed in the first direction D1.

A lower surface of a first one of the memory channel structures 550 disposed at a relatively upper level may be smaller than an upper surface of a second one of the memory channel structures 550 disposed at a relatively lower level, and may contact a central portion of the upper surface of the second one of the memory channel structures 550.

FIG. 46 shows that two second memory channel structures 550 are stacked in the first direction D1, however, the present disclosure is not limited thereto.

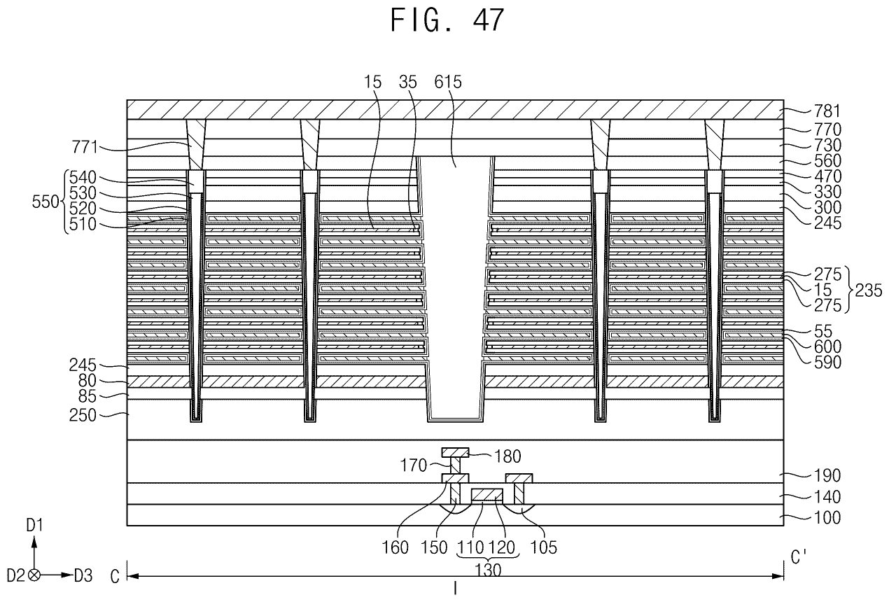

Referring to FIG. 47, the vertical memory device may have a COP structure, and thus the memory cells may be disposed over the lower circuit pattern.

The vertical memory device may not include the bonding layer structure 1000, and each of the memory channel structures 550 may have a width gradually increasing from a bottom toward a top thereof. Extension lengths in the second direction D2 of the second gate electrodes 600 included in the second gate electrode structure may decrease in a step wise manner from a lowermost level toward an uppermost level, and thus the second gate electrode structure may have a staircase shape.

In example embodiments, a channel connection pattern 85 and a support layer 80 may be sequentially stacked under the first insulation pattern 245 on the second substrate 250.

The memory channel structure 550 may extend through the channel connection pattern 85, the support layer 80 and an upper portion of the second substrate 250, and a portion of the memory channel structure 550 passing through the channel connection pattern 85 may not include the vertical charge storage structure 510. Thus, the channel connection pattern 85 may contact the channels 520 included in the memory channel structures 550, respectively, in each memory block, so that the channels 520 may be electrically connected to each other.

Each of the channel connection pattern 85 and the support layer 80 may include, e.g., undoped polysilicon or doped polysilicon.

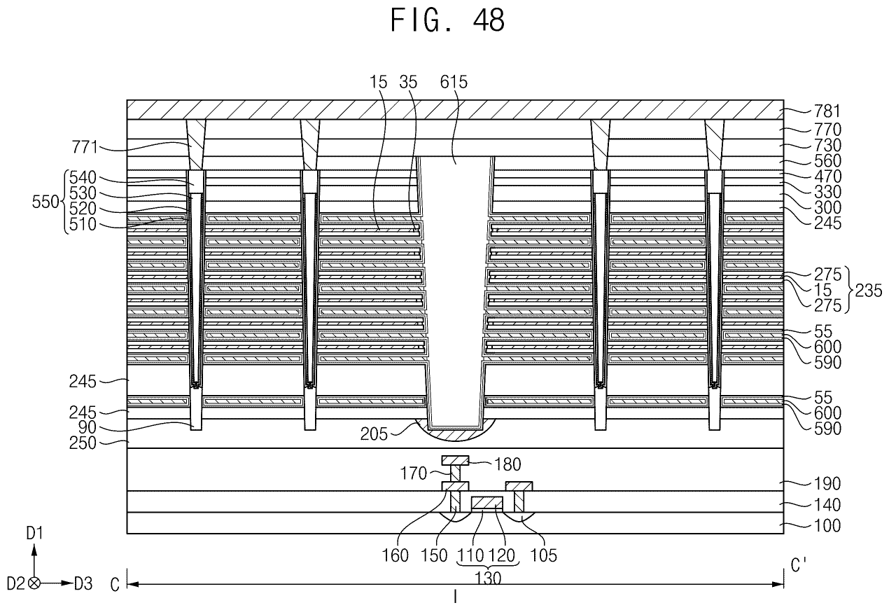

Referring to FIG. 48, the vertical memory device may have a COP structure, and thus the memory cells may be disposed over the lower circuit pattern.

The vertical memory device may not include the bonding layer structure 1000, and each of the memory channel structures 550 may be disposed on the second substrate 250, and may have a width gradually increasing from a bottom toward a top thereof. Extension lengths in the second direction D2 of the second gate electrodes 600 included in the second gate electrode structure may decrease in a stepwise manner from a lowermost level to an uppermost level, and thus the second gate electrode structure may have a staircase shape.

In example embodiments, a lower surface of the memory channel structure 550 may be disposed between lower and upper surfaces of the lower one of the first insulation patterns 245, and a semiconductor pattern 90 may be interposed between and electrically connect the second substrate 250 and the memory channel structure 550. The vertical charge storage structure 510 included in the memory channel structure 550 may have a shape of a cup of which a bottom is open, and may contact an upper surface of an edge of the semiconductor pattern 90.

The channel 520 included in the memory channel structure 550 may have a shape of a cup of which a sidewall is covered by the vertical charge storage structure 510, and may extend through the vertical charge storage structure 510 and contact an upper surface of a central portion of the semiconductor pattern 90.

The semiconductor pattern 90 may be formed by a selective epitaxial growth (SEG) process using the upper surface of the second substrate 250 as a seed, and may include a single crystalline semiconductor material, e.g., single crystalline silicon, single crystalline germanium, etc.

A second impurity region 205 may be disposed at a portion of the second substrate 250 under each of the first and second division patterns 610 and 615, and may serve as a common source line (CSL) of the vertical memory device.

In a method of manufacturing a semiconductor device, a sacrificial layer and an insulation layer structure may be alternately and repeatedly stacked on a substrate to form a mold layer. The insulation layer structure may include a horizontal charge storage layer and insulation layers on upper and lower surfaces, respectively, of the horizontal charge storage layer. A memory channel structure may be formed through the mold layer on the substrate, and may include a channel and a vertical charge storage structure surrounding a sidewall of the channel. An opening may be formed through the mold layer to expose an upper surface of the substrate. The sacrificial layer, the insulation layer structure, the mold layer, the horizontal charge storage layer and each of the insulation layers may be divided into sacrificial patterns, insulation structures, molds, horizontal charge storage patterns and insulation patterns, respectively. A portion of each of the horizontal charge storage patterns adjacent to the opening may be removed to form a first recess. A capping pattern may be formed in the first recess. Each of the sacrificial patterns may be removed through the opening to form a gap exposing a portion of a sidewall of the memory channel structure. A gate electrode may be formed in the gap.

In example embodiments, after forming the gap, a spacer layer may be formed on an inner wall of the gap and the portion of the sidewall of the memory channel structure exposed by the gap. The gate electrode may be formed on the spacer layer.

In example embodiments, the spacer layer may be formed on a sidewall of the capping pattern.

In example embodiments, a blocking layer may be formed, and the gate electrode may be formed on the blocking layer.

In example embodiments, when the first recess is formed, a portion of each of the sacrificial patterns adjacent to the opening may be removed to form a second recess.

In example embodiments, the opening may be formed to extend in a first direction parallel to an upper surface of the substrate. A depth of the second recess in a second direction parallel to the upper surface of the substrate and crossing the first direction may be greater than a depth of the first recess in the second direction.

In example embodiments, each of the horizontal charge storage patterns may contact the vertical charge storage structure, and the gate electrode may be spaced apart from the vertical charge storage structure.

In example embodiments, the vertical charge storage structure may include a tunnel insulation pattern, a vertical charge storage pattern and a blocking pattern sequentially disposed in a horizontal direction parallel to an upper surface of the substrate from a sidewall of the channel.

In example embodiments, the gate electrode and each of the horizontal charge storage patterns may extend in a first direction parallel to an upper surface of the substrate. A width of the gate electrode in a second direction parallel to an upper surface of the substrate and crossing the first direction may be greater than a width of each of the horizontal charge storage patterns in the second direction.

In example embodiments, the horizontal charge storage pattern may include silicon nitride or a metal oxide.

In some examples, a method of manufacturing a semiconductor device may include: forming a mold layer by alternately stacking a sacrificial layer and an insulation layer structure on a substrate, the insulation layer structure comprising (i) a horizontal charge storage layer and (ii) insulation layers on upper and lower surfaces of the horizontal charge storage layer, respectively; forming a memory channel structure extending through the mold layer on the substrate, the memory channel structure comprising (i) a channel and (ii) a vertical charge storage structure surrounding a sidewall of the channel; forming an opening through the mold layer to expose an upper surface of the substrate, wherein the sacrificial layer is divided into sacrificial patterns, the insulation layer structure is divided into insulation structures, the mold layer is divided into molds, the horizontal charge storage layer is divided into horizontal charge storage patterns, and each of the insulation layers is divided into insulation patterns; forming a first recess by removing a portion of each of the horizontal charge storage patterns adjacent to the opening; forming a capping pattern in the first recess; forming a gap exposing a portion of a sidewall of the memory channel structure by removing each of the sacrificial patterns through the opening; and forming a gate electrode in the gap.

While this specification contains many specific implementation details, these should not be construed as limitations on the scope of any disclosure or on the scope of what may be claimed, but rather as descriptions of features that may be specific to particular embodiments of particular disclosures. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations, one or more features from a combination can in some cases be excised from the combination, and the combination may be directed to a subcombination or variation of a subcombination.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present disclosure. Accordingly, all such modifications are intended to be included within the scope of example embodiments as defined in the claims.

What is claimed is:

1. A vertical memory device, comprising:
a substrate;
gate electrodes on the substrate, the gate electrodes being spaced apart from one another in a vertical direction perpendicular to an upper surface of the substrate;
a horizontal charge storage pattern between the gate electrodes; and
a memory channel structure extending through the gate electrodes and the horizontal charge storage pattern in the vertical direction, the memory channel structure comprising (i) a channel and (ii) a vertical charge storage structure surrounding a sidewall of the channel,
wherein the horizontal charge storage pattern contacts a sidewall of the vertical charge storage structure, and
wherein each of the gate electrodes is spaced apart from the vertical charge storage structure in a horizontal direction parallel to the upper surface of the substrate.

2. The vertical memory device of claim 1, comprising:
a first insulation pattern on a lower surface of the horizontal charge storage pattern; and
a second insulation pattern on an upper surface of the horizontal charge storage pattern.

3. The vertical memory device of claim 2, comprising a capping pattern between the first and second insulation patterns, the capping pattern contacting a sidewall of the horizontal charge storage pattern.

4. The vertical memory device of claim 2, comprising a spacer on (i) a lower surface of the first insulation pattern, (ii) an upper surface of the second insulation pattern, and (iii) the sidewall of the vertical charge storage structure.

5. The vertical memory device of claim 4, comprising a blocking pattern on (i) lower and upper surfaces of each of the gate electrodes and (ii) a sidewall of each of the gate electrodes facing the memory channel structure, the blocking pattern contacting the spacer.

6. The vertical memory device of claim 5, wherein the blocking pattern comprises a metal oxide, and the spacer comprises silicon oxide.

7. The vertical memory device of claim 1, wherein an air gap is defined between the horizontal charge storage pattern and each of the gate electrodes.

8. The vertical memory device of claim 1, wherein the horizontal charge storage pattern has a ring shape surrounding the memory channel structure.

9. The vertical memory device of claim 8, comprising an insulation pattern between the gate electrodes, the insulation pattern covering an upper surface, a lower surface, and a sidewall of the horizontal charge storage pattern.

10. The vertical memory device of claim 8, wherein an air gap is defined between the gate electrodes, the air gap surrounding an upper surface, a lower surface, and a sidewall of the horizontal charge storage pattern.

11. The vertical memory device of claim 1, wherein:
each of the gate electrodes has a planar shape extending in a first direction parallel to the upper surface of the substrate,
the horizontal charge storage pattern has a planar shape extending in the first direction and disposed between the gate electrodes, and
a width of the horizontal charge storage pattern in a second direction parallel to the upper surface of the substrate is less than a width of each of the gate electrodes in the second direction, the second direction crossing the first direction.

12. A vertical memory device, comprising:
a substrate;
gate electrodes on the substrate, the gate electrodes being spaced apart from one another in a vertical direction perpendicular to an upper surface of the substrate;
an insulation structure between the gate electrodes, the insulation structure comprising (i) a first insulation pattern, (ii) a horizontal charge storage pattern on the first insulation pattern in the vertical direction, and (iii) a second insulation pattern on the horizontal charge storage pattern in the vertical direction;
a capping pattern on a sidewall of the horizontal charge storage pattern;
a memory channel structure extending through the gate electrodes and the insulation structure in the vertical direction, the memory channel structure comprising a channel and a vertical charge storage structure that are arranged in a horizontal direction parallel to the upper surface of the substrate; and
a spacer on (i) a lower surface and a sidewall of the first insulation pattern, (ii) an upper surface and a sidewall of the second insulation pattern, (iii) a sidewall of the capping pattern, and (iv) a sidewall of a portion of the vertical charge storage structure facing each of the gate electrodes in the horizontal direction.

13. The vertical memory device of claim 12, comprising:
a blocking pattern on (i) an upper surface and a lower surface of each of the gate electrodes and (ii) a sidewall of each of the gate electrodes facing the memory channel structure, the blocking pattern contacting the spacer.

14. The vertical memory device of claim 12, wherein the horizontal charge storage pattern has a ring shape surrounding the memory channel structure.

15. The vertical memory device of claim 14, wherein an air gap is defined between the gate electrodes, the air gap surrounding an upper surface, a lower surface, and a sidewall of the horizontal charge storage pattern.

16. The vertical memory device of claim 12, wherein:
each of the gate electrodes has a planar shape extending in a first direction parallel to the upper surface of the substrate,
the horizontal charge storage pattern has a planar shape extending in the first direction and disposed between the gate electrodes, and
a width of the horizontal charge storage pattern in a second direction parallel to the upper surface of the substrate is less than a width of each of the gate electrodes in the second direction, the second direction crossing the first direction.

17. A vertical memory device, comprising:
gate electrodes on a substrate, the gate electrodes being spaced apart from each other in a vertical direction perpendicular to an upper surface of the substrate, and each of the gate electrodes extending in a first direction parallel to the upper surface of the substrate;
an insulation structure between the gate electrodes, the insulation structure comprising (i) a horizontal charge storage pattern extending in the first direction, and (ii) insulation patterns on lower and upper surfaces of the horizontal charge storage pattern, respectively;
a capping pattern between the insulation patterns, the capping pattern being disposed on a sidewall of the horizontal charge storage pattern in a second direction parallel to the upper surface of the substrate and crossing the first direction;
a memory channel structure extending through the gate electrodes and the insulation structure in the vertical direction, the memory channel structure comprising (i) a filling pattern extending in the vertical direction, (ii) a channel surrounding the filling pattern, and (iii) a vertical charge storage structure surrounding the channel; and
a spacer on (i) a lower surface, an upper surface, and a portion of a sidewall of the insulation structure, (ii) a sidewall of the capping pattern, and (iii) a sidewall of a portion of the vertical charge storage structure facing each of the gate electrodes in the horizontal direction.

18. The vertical memory device of claim 17, comprising:
a blocking pattern on (i) an upper surface and a lower surface of each of the gate electrodes and (ii) a sidewall of each of the gate electrodes facing the memory channel structure in the horizontal direction, the blocking pattern contacting the spacer.

19. The vertical memory device of claim 17, wherein a width of the horizontal charge storage pattern in the second direction is less than a width of each of the gate electrodes in the second direction.

20. The vertical memory device of claim 17, wherein the insulation structure contacts a sidewall of the memory channel structure, and each of the gate electrodes is spaced apart from the sidewall of the memory channel structure in the horizontal direction.
